(19) United States
(12) Patent Application Publication
(10) Pub. No.: US 2025/0219219 A1
(43) Pub. Date: Jul. 3, 2025

(54) CONTAINER DEVICE

(71) Applicant: HONDA MOTOR CO., LTD., Tokyo (JP)

(72) Inventors: Yuki Yoshimine, Wako-shi (JP); Masashi Kai, Wako-shi (JP); Kosuke Yamana, Wako-shi (JP); Kenta Sugitate, Wako-shi (JP)

(21) Appl. No.: 18/850,742

(22) PCT Filed: Mar. 31, 2023
(86) PCT No.: PCT/JP2023/013522

§ 371 Date: Sep. 25, 2024

(30) Foreign Application Priority Data
Mar. 31, 2022 (JP) 2022-060156
Aug. 29, 2022 (JP) 2022-136282
Sep. 15, 2022 (JP) 2022-147335

(51) Int. Cl. H01M 50/242; H01M 10/48; H01M 50/256; H01M 50/271

(52) U.S. Cl. CPC H01M 50/242; H01M 10/488; H01M 50/256; H01M 50/271

(57) ABSTRACT

A container device includes a housing having six substantially quadrangular surfaces facing mutually different directions, the housing being formed in a substantially polyhedral shape, and a container portion provided inside the housing. The container portion contains a contained item to enable the contained item to be inserted and removed. The housing has a first member and a second member, the first member and the second member each being attached to the container portion, and the second member is attached to an opposite side of the first member across the container portion.

### TECHNICAL FIELD

The present invention relates to a container device.

### BACKGROUND ART

Conventionally, a vehicle battery container device is known, the vehicle battery container device including a container portion that attachably/detachably contains a battery (for example, refer to Patent Literature 1). Moreover, there is a container device that includes a container portion of a battery such as in Patent Literature 1 (for example, refer to Patent Literature 2). This container device includes a housing for storing the container portion inside.

### CITATION LIST

### Patent Literature

### [Patent Literature 1]

International Patent Publication No. WO 2019/064593

### [Patent Literature 2]

International Patent Publication No. WO 2020/235637

### SUMMARY OF INVENTION

### Technical Problem

However, in a conventional container device, a fixing structure or the like between the container portion and the housing is not clear, and there is room for improvement in the strength of the housing. The present invention has an objective to provide a container device that can improve the strength.

### Solution to Problem

All of the content of Japanese Patent Application No. 2022-060156 filed on Mar. 31, 2022, Japanese Patent Application No. 2022-136282 filed on Aug. 29, 2022, and Japanese Patent Application No. 2022-147335 filed on Sep. 15, 2022 is included in this specification. The present invention is a container device that includes a housing having six substantially quadrangular surfaces facing mutually different directions, the housing being formed in a substantially polyhedral shape, and a container portion provided inside the housing, the container portion containing a contained item to enable the contained item to be inserted and removed, in which the housing has a first member and a second member, the first member and the second member each being attached to the container portion, and the second member is attached to an opposite side of the first member across the container portion.

### Advantageous Effect of Invention

According to the present invention, the strength can be improved.

### BRIEF DESCRIPTION OF DRAWINGS

FIG. 1 is a perspective view of a container device relating to an embodiment of the present invention.

FIG. 2 is an exploded perspective view of a housing.

FIG. 3 is a longitudinal cross-section view in which the container device is cut at Plane III shown in FIG. 1.

FIG. 4 is an exploded perspective view of the container device.

FIG. 5 is a perspective view in which a battery is seen from above.

FIG. 6 is a perspective view in which the battery is seen from below.

FIG. 7 is a perspective view in which a container mechanism is seen from above.

FIG. 8 is a planar view of a battery case.

FIG. 9 is a perspective view in which a bottom portion of the battery case is seen from below.

FIG. 10 is a perspective view of a case frame body.

FIG. 11 is a schematic view in which the container mechanism is seen from a right direction of the container device.

FIG. 12 is a schematic view in which the container mechanism is seen from a left direction of the container device.

FIG. 13 is a longitudinal cross-section view in which the container device is cut at Plane XIII shown in FIG. 1.

FIG. 14 is a longitudinal cross-section view in which the container device is cut at Plane XIV shown in FIG. 1.

FIG. 15 is a longitudinal cross-section view in which the container device is cut at Plane XV shown in FIG. 1.

FIG. 16 is a perspective view showing an assembly structure of the container device.

FIG. 17 is a perspective view showing an assembly structure of the container device.

FIG. 18 is a perspective view in which the container device is seen from the left side.

FIG. 19 is a side surface view in which the container device is seen from the right side.

### DESCRIPTION OF EMBODIMENTS

### 1. Embodiment

### (1.1. Configuration)

Hereinafter, an embodiment of the present invention will be described by referring to the figures. In each of the figures, reference symbol FR shows the front in a state where a container device 1 is installed (loaded) with a lower surface as a bottom surface in contact with an installation surface, reference symbol UP shows above the container device 1, and reference symbol LH shows the left of the container device 1. In the following description, as long as there is no particular description, each direction is a direction along these directions of the container device 1. Hereinafter, a so-called upright posture is called a first posture, the so-called upright posture being a state where the container device 1 is installed with a lower surface as a bottom surface in contact with an installation surface.

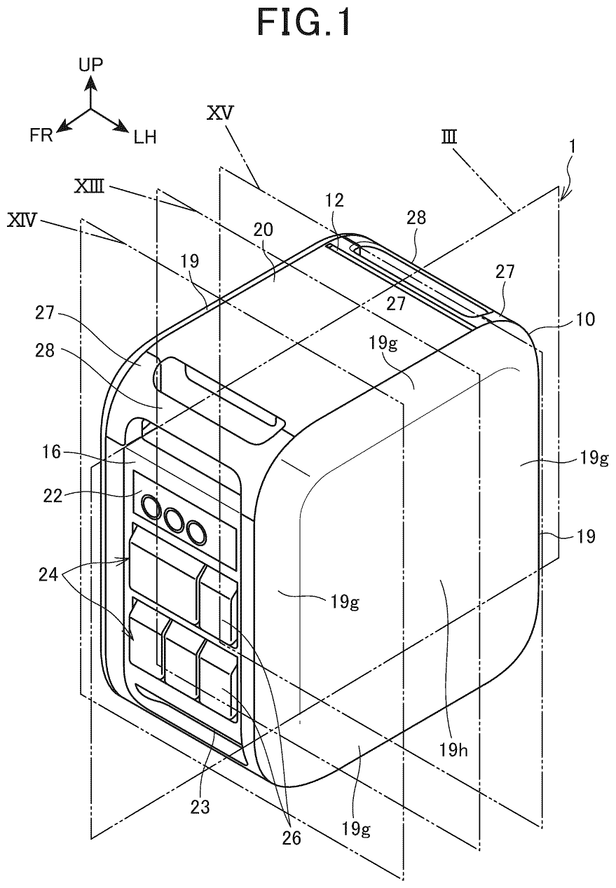

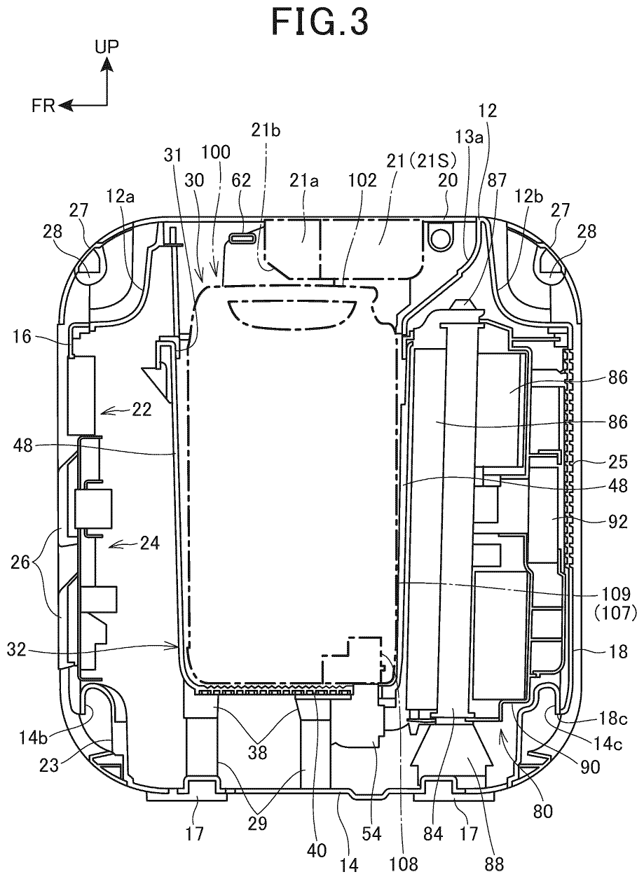

FIG. 1 is a perspective view of the container device 1 relating to an embodiment of the present invention. The container device 1 contains a battery 100 capable of being attached/detached to/from the container device 1, the container device 1 converts electrical power stored in the battery 100 in accordance with an operation of a user (user), and the container device 1 functions as an electrical power supply device for supplying electrical power to an electric device or the like outside of the container device 1 (FIG. 3). As shown in FIG. 1, the container device 1 includes a substantially quadrangular parallelepiped housing 10. The housing 10 includes an upper surface, a lower surface, a front surface, a rear surface, and a pair of side surfaces positioned on the left and right, the upper surface, the lower surface, the front surface, the rear surface, and the pair of side surfaces all being flat surfaces. In a first posture of the container device 1, the lower surface of the housing 10 becomes the bottom surface in contact with the installation surface. Note that, the housing 10 is not limited to a quadrangular parallelepiped shape, and the housing 10 may have any type of shape, for example, if the shape has six substantially quadrangular surfaces facing mutually different directions, and if the shape is substantially polyhedral, such as a substantially cubic shape.

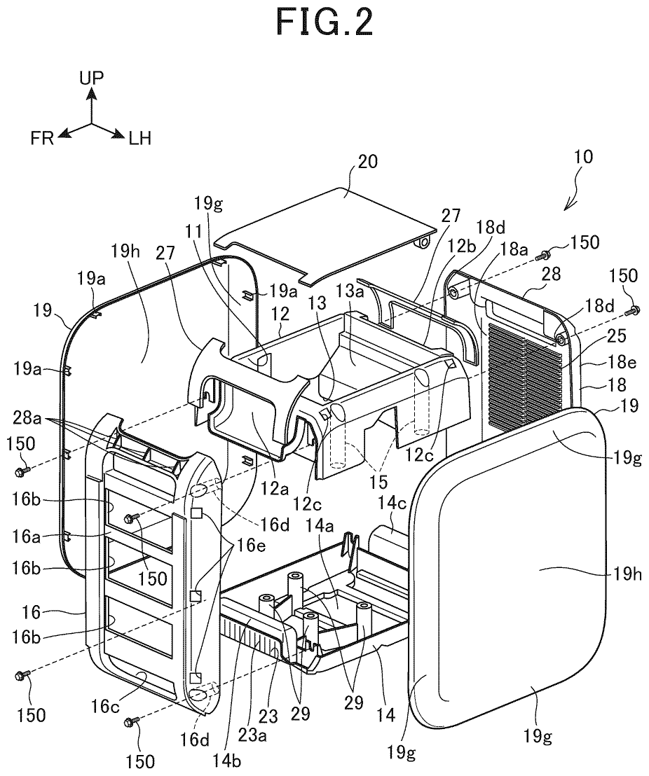

FIG. 2 is an exploded perspective view of the housing 10. In FIG. 2, the members stored inside the housing 10, such as a container mechanism 30 and an inverter unit 80, are omitted. As shown in FIG. 2, the housing 10, in the first posture of the container device 1, includes an upper surface panel 12 forming the upper surface, a lower surface panel 14 forming the lower surface, the lower surface becoming the bottom surface, a front surface panel 16 forming the front surface, a rear surface panel 18 forming the rear surface, and a pair of side surface panels 19 forming each of the left and right side surfaces. In the present embodiment, while each panel is formed by a resin material, the present invention is not limited to this, and a portion of at least one or any number of the panels may be formed by another material such as a metallic material.

The upper surface panel 12 is a member formed so as to include a predetermined thickness dimension, by forming the upper surface panel 12 so that each edge portion of a substantially rectangular plate shaped material is folded downward along an up-down direction of the container device 1. An upper surface recessed portion 11 is provided on the upper surface panel 12, a substantial center of the upper surface recessed portion 11 being recessed in a rectangular shape in a planar view from an upper surface side toward a lower surface side. An upper surface opening 13 is provided at a substantial center of a bottom surface of the upper surface recessed portion 11, the upper surface opening 13 being a substantially rectangular shaped through hole in a planar view. Screw holes 15 are provided, at positions in the vicinity of each corner portion of the upper surface opening 13, on the bottom surface of the upper surface recessed portion 11, the screw holes 15 being through holes. Engagement holes 12c are provided, at positions adjacent to each of the screw holes 15, the engagement holes 12c being recessed portions with which a claw shaped member can engage.

A front surface plate 12a is provided on a front end of the upper surface panel 12, the front surface plate 12a extending toward a lower portion of the housing 10. The front surface plate 12a extends downward, the front surface plate 12a is thereafter gently inclined, and the front surface plate 12a extends toward the front of the housing 10. The front surface plate 12a is formed so as to draw an arc seen from a left-right direction of the housing 10. Similarly, a rear surface plate 12b is provided on a rear end of the upper surface panel 12, the rear surface plate 12b extending toward a lower portion of the housing 10 (FIG. 3). The rear surface plate 12b extends downward, the rear surface plate 12b is thereafter gently inclined, and the rear surface plate 12b extends toward the rear of the housing 10. The rear surface plate 12b is formed so as to draw an arc seen from a left-right direction of the housing 10. The upper surface panel 12 corresponds to a “first member”. This upper surface panel 12 forms a first surface, from among the six surfaces of the housing 10.

A rectangular shaped cover body 20 is provided on the upper surface panel 12, the rectangular shape being in a planar view. The cover body 20 is rotatably fixed to an edge portion of the upper surface recessed portion 11, the edge portion being positioned on a rear side of the upper surface panel 12. The cover body 20 covers the entire upper surface recessed portion 11 and the entire upper surface opening 13, and the cover body 20 can be opened, by having a user rotate the cover body 20. On the upper surface panel 12, an upper surface of this cover body 20 forms a greater portion of the upper surface of the housing 10.

An expanded portion 21 is provided, on a lower surface opposite the upper surface opening 13, on the cover body 20, the expanded portion 21 being formed by having substantially the entire surface of the lower surface expanded toward the upper surface opening 13. According to this, the strength of the cover body 20 increases, and the housing 10 and the cover body 20 have an external pressure toughness from the outside that is improved. Namely, the expanded portion 21 functions as a reinforcement member of the cover body 20. In this expanded portion 21, the inside is formed hollow, and an inside space 21S is provided. A cover portion 21a is formed, at a front surface side of the housing 10, on the expanded portion 21, the cover portion 21a capable of being opened and closed by rotating with respect to a rear surface side of the expanded portion 21 in the housing 10. According to this, in a state where the cover body 20 is opened, when the cover portion 21a is opened, the expanded portion 21 opens toward the upside. Accordingly, in the container device 1, it becomes easy for a user to insert and remove a predetermined item from the inside of the expanded portion 21. It is possible to store various types of cables, such as an electrical power cable for inputting electrical power from the outside to the container device 1, inside the expanded portion 21.

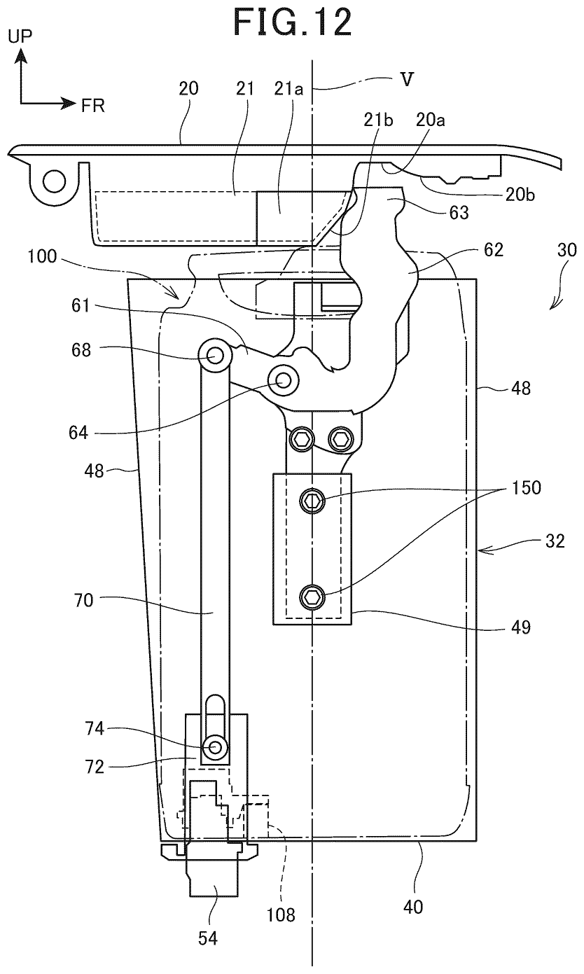

A chamfered portion 21b is provided, at a front surface side in the housing 10 and at a lower portion side of the housing 10, on the cover portion 21a, the chamfered portion 21b being formed by having corner portions of the cover portion 21a chamfered, seen from the side of the housing 10 (FIG. 3, FIG. 12). The chamfered portion 21b is provided across the entire width direction of the cover portion 21a extending along a left-right direction of the housing 10.

A cover body recessed portion 20a is provided, at a location positioned more on a front surface side of the housing 10 than the expanded portion 21, on a lower surface of the cover body 20 opposite the upper surface opening 13 (FIG. 12). The cover body recessed portion 20a is formed by having a lower surface of the cover body 20 linearly recessed toward the upside of the housing 10. The cover body recessed portion 20a is provided across the entire width direction of the cover portion 21a along a left-right direction of the housing 10. A chamfered portion 20b is provided, at a position opposite the expanded portion 21, on an inner side surface of the cover body recessed portion 20a, the chamfered portion 20b being formed by having an inner side surface of the cover body recessed portion 20a chamfered, seen from the side of the housing 10 (FIG. 12). The chamfered portion 20b is provided across the entire width direction of the cover body recessed portion 20a extending along a left-right direction of the housing 10.

An opening inclined surface 13a is provided, from the rear to the front of the housing, at an edge portion of the upper surface opening 13 positioned on a rear side of the housing 10, on the upper surface panel 12, the opening inclined surface 13a being an inclined surface that is gently inclined. An upper end of the opening inclined surface 13a is positioned on the rear of the cover body 20, and the upper end of the opening inclined surface 13a is coupled to an upper end of the rear surface plate 12b. The opening inclined surface 13a is inclined to a position substantially the same as a lower end of the upper surface panel 12, along a thickness direction of the upper surface panel 12, on an inner side of the upper surface opening 13.

The lower surface panel 14 is a member formed so as to include a predetermined thickness dimension, by folding each edge portion of a substantially rectangular plate shaped material upward along an up-down direction of the container device 1. A flat surface 14a is provided at a substantial center of the lower surface panel 14. A hand hooking portion 14b and a hand hooking portion 14c are provided on each of a front end and a rear end of the lower surface panel 14.

The hand hooking portion 14b is erected from a front end of the lower surface panel 14 toward the upside of the housing 10, and thereafter the hand hooking portion 14b extends to a front surface side of the housing 10, while the hand hooking portion 14b is bent in a so-called arch shape, seen from a left-right direction of the housing 10, the so-called arch shape being a projecting shape drawing an arc toward the upside. Similarly, the hand hooking portion 14c is erected from a rear end of the lower surface panel 14 toward the upside of the housing 10, and thereafter the hand hooking portion 14c extends to a rear surface side of the housing 10, while the hand hooking portion 14c is bent in a so-called arch shape, seen from a left-right direction of the housing 10, the so-called arch shape being a projecting shape drawing an arc toward the upside. A tip end of each of the hand hooking portion 14b and the hand hooking portion 14c is positioned more upward than the flat surface 14a of the lower surface panel 14. A user can transport the container device 1, by having the user place his or her fingers or hands on the hand hooking portion 14b and the hand hooking portion 14c.

A front surface air intake slot 23 is provided, at a location erected from a front end of the lower surface panel 14 toward the upside of the housing 10, on the hand hooking portion 14b, the front surface air intake slot 23 being a through hole. This front surface air intake slot 23 is formed in a long hole shape extending along a left-right direction of the housing 10. An upper edge of the front surface air intake slot 23 is positioned more downward than the tip end of the hand hooking portion 14b.

A plurality of leg portions 17 is provided on the flat surface 14a, the plurality of leg portions 17 protruding toward the outside of the housing 10. In the first posture, the container device 1 is supported by these leg portions 17. In the first posture, the lower surface panel 14 is disposed vertically downward, in an up-down direction of the housing 10. The leg portions 17 are formed, for example, by various types of resin materials such as a rubber material. The lower surface panel 14 corresponds to a “second member”. This lower surface panel 14 forms a second surface, from among the six surfaces of the housing 10. The lower surface panel 14 is disposed, opposite the first surface, so that the second surface extends in parallel, the first surface being where the upper surface panel 12 is formed.

A plurality of louvers 23a is provided on the front surface air intake slot 23. Each of the louvers 23a is formed in a shape drawing an S-shape in a planar view. Each of the louvers 23a is disposed so that a tip end of a front surface side of the housing 10 overlaps a rear end of another adjacent one of the louvers 23a. According to this, a so-called labyrinth structure is formed, from a front surface side to a rear surface side of the housing 10, on the front surface air intake slot 23. According to this, in the housing 10, foreign objects such as dust and garbage entering the inside from the outside of the housing 10, via the front surface air intake slot 23, is suppressed.

As shown in FIG. 2, the front surface panel 16 is a member formed so as to include a predetermined thickness dimension, by having each edge portion of a substantially rectangular plate shaped material folded to the rear side so as to form a curved surface, along a front-rear direction of the container device 1. A flat surface 16a is provided at a substantial center of the front surface panel 16. A unit opening 16b is provided on the flat surface 16a, the unit opening 16b being a through hole. In the present embodiment, the unit opening 16b is a rectangular long hole extending along a left-right direction of the housing 10, and three of the unit openings 16b are provided, along an up-down direction of the housing 10.

A front surface opening 16c is formed more downward than the unit opening 16b, the front surface opening 16c being a rectangular long hole extending along a left-right direction of the housing 10.

A rod-shaped handle 28 is provided, at a position more in the vicinity of an upper surface side than a lower surface side of the housing 10, on the front surface panel 16, the rod-shaped handle 28 extending along a left-right direction of the housing 10. A lower edge of the handle 28 is formed, on a front surface side of the housing 10, by having a portion positioned more upward than the unit opening 16b hollowed out into a long hole shape. An upper edge of the handle 28 is formed by having a substantial center of an upper end of the front surface panel 16 notched along an up-down direction of the housing 10. According to this, each of the handles 28 is provided without protruding from each surface of the housing 10. Accordingly, it is possible to improve designability and operability of the container device 1.

The handle 28 is formed hollow. A side surface is integrally formed with the front surface panel 16, on this handle 28, the side surface being coupled from a position opposite the rear across a position opposite the bottom. A plurality of ribs 28a is provided on the inside of the handle 28, the plurality of ribs 28a extending erected in a direction orthogonal to a longitudinal direction of the handle 28. According to this, it is possible for the handle 28 to include a predetermined strength. A side surface positioned on an outer side of the container device 1 is formed, on the handle 28, by a handle cover 27 separate from the front surface panel 16. The handle cover 27 is attached to the front surface panel 16. According to this, it is possible for the handle 28 to be formed hollow, and it is possible for the handle 28 to be reduced in weight.

It becomes possible for a user to transport or install the container device 1 by holding these handles 28. Note that, the handle 28 is not limited to a shape in which the user can grip the entire circumference, such as stated above, and the handle 28 may have another shape, for example, in which a user can hold the container device 1 by the user placing his or her fingers or hands, such as a groove shape. Namely, the container device 1 may have a recessed portion or the like that is provided so as to become a hand hook for a user to hold.

Screw holes 16d are provided, at portions adjacent to each corner portion of the flat surface 16a, on the front surface panel 16. Engagement holes 16e are provided, at each edge portion extending along an up-down direction of the housing 10, on the flat surface 16a, the engagement holes 16e being recessed portions with which a claw shaped member can engage.

The rear surface panel 18 is a member formed so as to include a predetermined thickness dimension, by folding each edge portion of a substantially rectangular plate shaped member to the front side so as to form a curved surface, along a front-rear direction of the container device 1. A flat surface 18a is provided at a substantial center of the rear surface panel 18. A rear surface discharge slot 25 is provided on the flat surface 18a, the rear surface discharge slot 25 being a through hole. In the present embodiment, the rear surface discharge slot 25 is formed in a rectangular shape in a planar view of the rear surface panel 18, and the rear surface discharge slot 25 is provided at a position more in the vicinity of an upper surface side than a lower surface side of the housing 10. A plurality of louvers is provided on the rear surface discharge slot 25. Note that, at least either the front surface panel 16 or the rear surface panel 18 is not limited to one member, and at least either the front surface panel 16 or the rear surface panel 18 may be formed from two or more members.

A rear surface opening 18c (FIG. 3) is formed more downward than the rear surface discharge slot 25, the rear surface opening 18c being a rectangular long hole extending along a left-right direction of the housing 10.

As shown in FIG. 2, a rod-shaped handle 28 is provided, at a position more in the vicinity of an upper surface side than a lower surface side of the housing 10, on the rear surface panel 18, the rod-shaped handle 28 extending along a left-right direction of the housing 10. The handle 28 of the rear surface panel 18 is formed in substantially the same shape as the handle 28 of the front surface panel 16. A lower edge of the handle 28 is formed, on a front surface side of the housing 10, by having a portion positioned more upward than the rear surface discharge slot 25 hollowed out into a long hole shape. An upper edge of the handle 28 is formed by having a substantial center of an upper end of the rear surface panel 18 notched along an up-down direction of the housing 10.

The handle 28 is formed hollow. A side surface is integrally formed with the rear surface panel 18, on this handle 28, the side surface being coupled from a position opposite the front across a position opposite the bottom. A plurality of ribs 28a is provided on the inside of the handle 28, the plurality of ribs 28a extending erected in a direction orthogonal to a longitudinal direction of the handle 28. A side surface positioned on an outer side of the container device 1 is formed, on the handle 28, by a handle cover 27 separate from the rear surface panel 18. The handle cover 27 is attached to the rear surface panel 18.

Screw holes 18d are provided, at portions adjacent to each corner portion of the flat surface 18a, on the rear surface panel 18. Engagement holes 18e are provided, at each edge portion extending along an up-down direction of the housing 10, on the flat surface 18a, the engagement holes 18e being recessed portions with which a claw shaped member can engage. The front surface panel 16 and the rear surface panel 18 each correspond to a “third member”. Each of the front surface panel 16 and the rear surface panel 18 forms two third surfaces, from among the six surfaces of the housing 10. The front surface panel 16 and the rear surface panel 18 are each disposed so that the two third surfaces extend in parallel to one another.

As shown in FIG. 1 and FIG. 2, an upper end of the front surface panel 16 is coupled to a front end of the upper surface panel 12, and an upper end of the rear surface panel 18 is coupled to a rear end of the upper surface panel 12. A lower end of the front surface panel 16 is coupled to a front end of the lower surface panel 14, and a lower end of the rear surface panel 18 is coupled to a rear end of the lower surface panel 14.

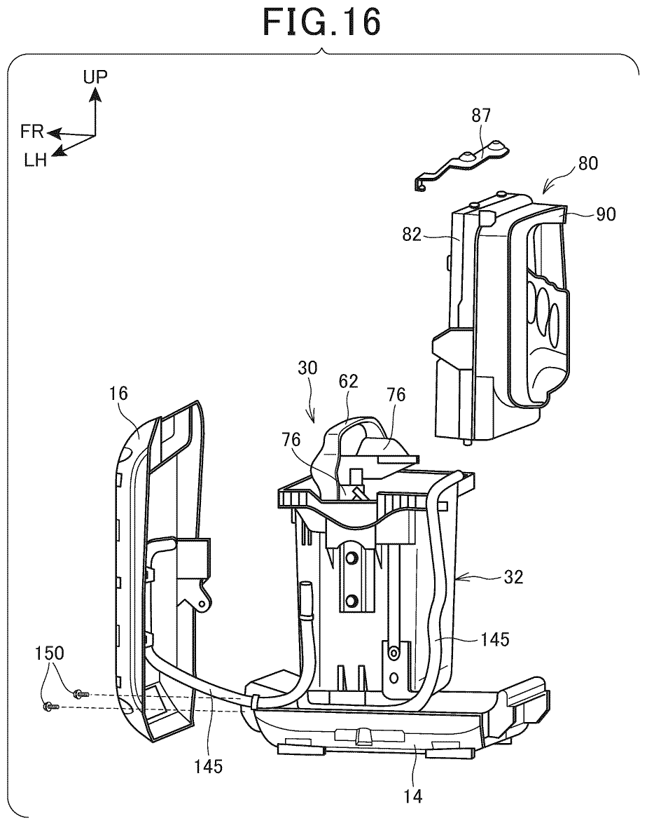

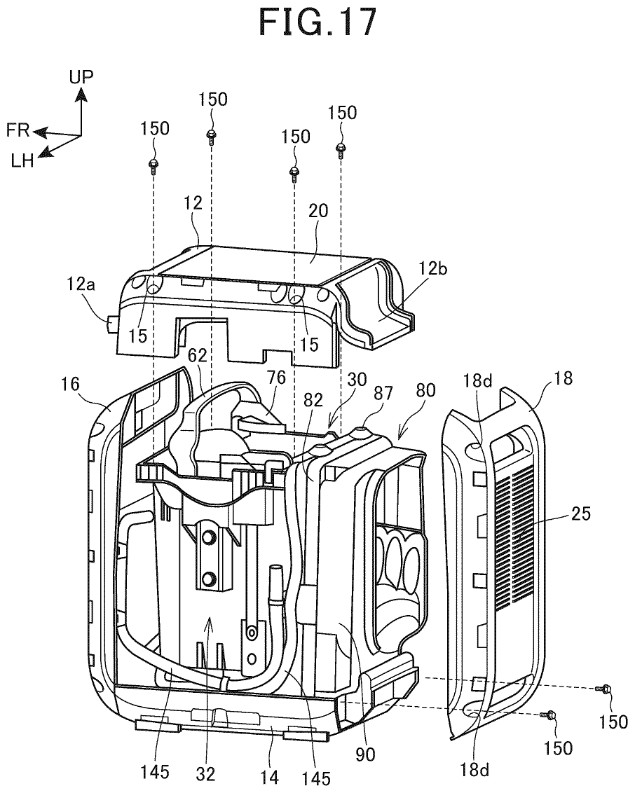

Specifically, a fastening member 150 is screwed into a front end of the upper surface panel 12, the fastening member 150 being inserted into each of the screw holes 16d on an upper end side of the front surface panel 16 (FIG. 2), and a fastening member 150 is screwed into a front end of the lower surface panel 14, the fastening member 150 being inserted into each of the screw holes 16d on a lower end side of the front surface panel 16 (FIG. 16). Similarly, a fastening member 150 is screwed into a rear end of the upper surface panel 12, the fastening member 150 being inserted into each of the screw holes 18d on the upper end side of the rear surface panel 18 (FIG. 2), and a fastening member 150 is screwed into a rear end of the lower surface panel 14, the fastening member 150 being inserted into each of the screw holes 18d on a lower end side of the rear surface panel 18 (FIG. 17).

When the upper surface panel 12 and the front surface panel 16 are coupled, a circumferential surface of the handle 28 and the front surface plate 12a are disposed opposite one another. A tip end of the front surface plate 12a extends to below the handle 28, and the front surface plate 12a forms a curved surfaces opposite the circumferential surface of the handle 28. Similarly, when the upper surface panel 12 and the rear surface panel 18 are coupled, a circumferential surface of the handle 28 and the rear surface plate 12b are disposed opposite one another. A tip end of the rear surface plate 12b extends to below the handle 28, and the rear surface plate 12b forms a curved surface opposite the circumferential surface of the handle 28.

In the case where a user holds each of the handles 28, a hand is inserted between each of the handles 28 and either the front surface plate 12a or the rear surface plate 12b. The front surface plate 12a and the rear surface plate 12b are formed from one member, and the front surface plate 12a and the rear surface plate 12b form a jointless curved surface. Accordingly, in the container device 1, in the case where a hand is inserted between each of the handles 28 and either the front surface plate 12a or the rear surface plate 12b, a joint or the like does not come into contact with the hand of the user.

When the lower surface panel 14 and the front surface panel 16 are coupled, the hand hooking portion 14b and the front surface air intake slot 23 are exposed on a front surface side of the housing 10, via the front surface opening 16c. A tip end of the hand hooking portion 14b is coupled to an upper edge of the front surface opening 16c. Similarly, when the lower surface panel 14 and the front surface panel 16 are coupled, the hand hooking portion 14c is exposed on a rear surface side of the housing 10, via the rear surface opening 18c. A tip end of the hand hooking portion 14c is coupled to an upper edge of the rear surface opening 18c. It is possible for a user to transport the container device 1, by having the user place his or her fingers or hands on the hand hooking portion 14b and the hand hooking portion 14c, via the front surface opening 16c or the rear surface opening 18c.

Each of the side surface panels 19 is a substantially rectangular plate shaped member in a planar view. Each of the corner portions of the side surface panel 19 are rounded by being so-called R-chamfered. An inclined surface 19g is formed, from each side of the side surface panel 19, each side being an outer edge, toward flat surfaces 19h of the housing 10, the flat surfaces 19h being left and right side surfaces, on the side surface panel 19, the inclined surface 19g being gently inclined. When each of the side surface panels 19 is coupled to the other panels, each of the inclined surfaces 19g becomes a surface connected to each of the upper surface, the lower surface, the front surface, and the rear surface of the housing 10. On each of the side surface panels 19, the flat surface 19h positioned in the center is a flat portion, and the flat surface 19h functions as a main surface for forming a greater portion of a side surface around the housing 10. Each of the side surface panels 19 corresponds to a “fourth member”. Each of the side surface panels 19 forms two fourth surfaces, from among the six surfaces of the housing 10. Each of the side surface panels 19 is disposed so that the two fourth surfaces extend in parallel to one another.

A plurality of engagement pieces 19a is provided, on each of three sides, on each of the side surface panels 19, the three sides excluding the side positioned on a lower end side of the housing 10 in an up-down direction, the plurality of engagement pieces 19a protruding from a surface positioned on an inner side of the housing 10. Each of the side surface panels 19 is attached to each of these panels, by engaging each of these engagement pieces 19a, from both the left and right, with each of the engagement holes 12c of the upper surface panel 12, each of the engagement holes 16e of the front surface panel 16, and each of the engagement holes 18e of the rear surface panel 18. Note that, the present invention is not limited to this, and each of the side surface panels 19 may be fixed to each panel by using a fastening member. Moreover, for example, at least one of each of the side surface panels 19 is not limited to one member, and at least one of each of the side surface panels 19 may be formed from two or more members.

The container device 1 can be installed with one of the left-right side surfaces, namely, one of each of the side surface panels 19, as a bottom surface. Hereinafter, a so-called lying posture is called a second posture, the so-called lying posture being a state where the container device 1 is installed with one of the left-right side surfaces as a bottom surface.

As shown in FIG. 1 and FIG. 2, when each of the side surface panels 19 is attached to the upper surface panel 12, the lower surface panel 14, the front surface panel 16, and the rear surface panel 18, each of the screw holes 16d and each of the screw holes 18d are covered by each of the side surface panels 19.

As shown in FIG. 1, a user interface unit 22 is provided, positioned more in the vicinity of an upper surface side than a lower surface side, on the front surface panel 16, the user interface unit 22 being positioned on a front surface of the housing 10. The user interface unit 22 includes a display area on which Light Emitting Diodes (LEDs) or the like are provided, the display area displaying an operation state of the container device 1, a remaining amount of energy of the battery 100 or the like, and the user interface unit 22 includes a switch area on which a switch is provided, the switch being an operator for receiving an operation, such as a switching instruction of an operation state of the container device 1, from a user. Note that, the user interface unit 22 is not limited to a physical switch, and the user interface unit 22 may be formed to be operatable by a touch panel provided on the display area. The display area corresponds to a “display portion”, and the switch area corresponds to an “operation portion”.

A terminal unit 24 is provided, more downward than the user interface unit 22, on the front surface panel 16. The terminal unit 24 includes an AC power output terminal and a DC power output terminal. The AC power output terminal and the DC power output terminal supply AC power and DC power to another electric device or the like, via outside terminals that are respectively connected to the AC power output terminal and the DC power output terminal. The terminal unit 24 includes an operator for receiving a predetermined operation with respect to the container device 1, and the terminal unit 24 includes a connection terminal connected to another container device 1.

The terminal unit 24 includes an AC power input terminal and a DC power input terminal. AC power or DC power is supplied from a power generating device outside the container device 1, such as an AC output portion (outlet) of a generator, a house or the like, or a solar panel, via external terminals respectively connected to the AC power input terminal and the DC power input terminal. It is possible for the container device 1 to perform charging of the battery 100 contained inside, by using the input AC power or DC power. Namely, the container device 1 functions as a charging device.

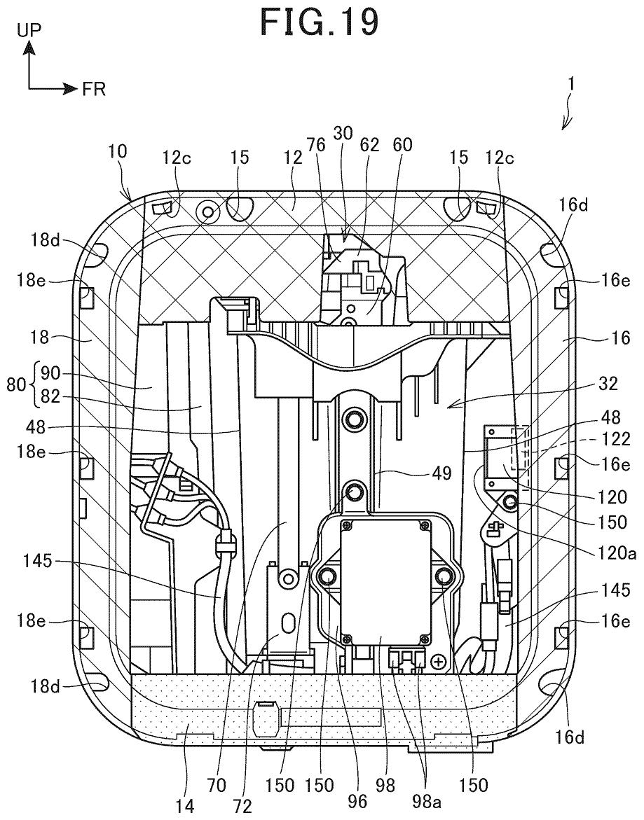

A cover member 26 is provided on the terminal unit 24, the cover member 26 covering each of the above-stated various terminals and operator. The cover member 26 is provided to be capable of attaching/detaching to/from the terminal unit 24. Note that, the cover member 26 may be integrally provided with the terminal unit 24, and the cover member 26 may be formed to be capable of opening/closing. A communication unit 120 is attached to the side of the terminal unit 24 (FIG. 19).

The user interface unit 22, the terminal unit 24, and the communication unit 120 are attached to a flat surface of the rear surface panel 16 on the rear side in the housing 10, in a state where the user interface unit 22, the terminal unit 24, and the communication unit 120 are coupled to one another beforehand. In the user interface unit 22 and the terminal unit 24 attached in such a way, the display area, the switch area, the various types of terminals, and the operator are exposed to a front surface side of the housing 10, by inserting the display area, the switch area, the various types of terminals, and the operator into the unit opening 16b.

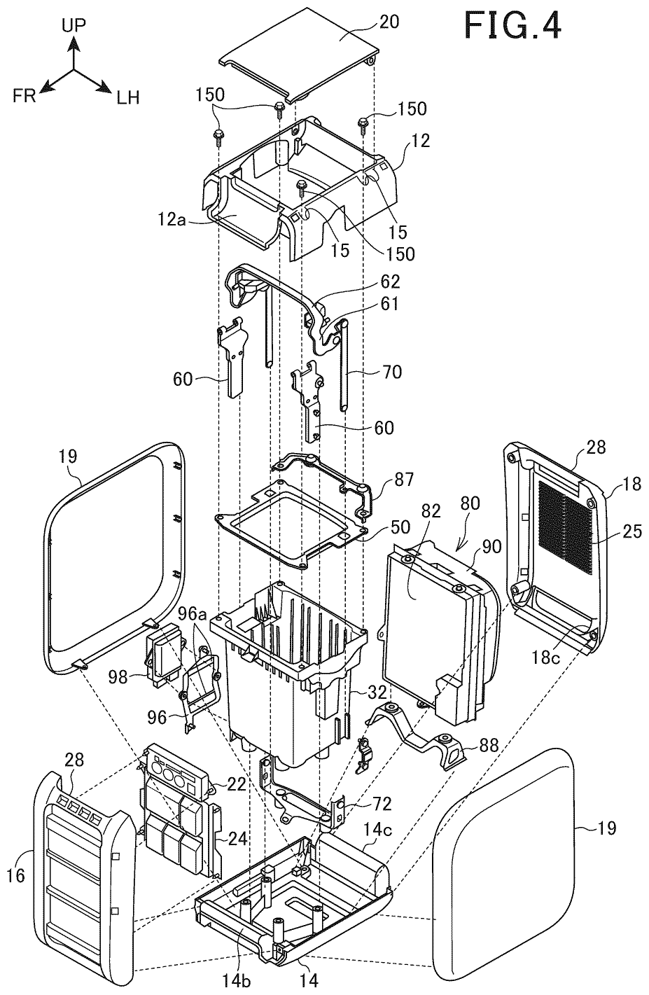

FIG. 3 is a longitudinal cross-section view in which the container device 1 is cut at Plane III shown in FIG. 1. Plane III is a virtual surface passing through a substantial center of the container device 1 in a left-right direction. FIG. 4 is an exploded perspective view of the container device 1. As shown in FIG. 3 and FIG. 4, a container mechanism 30 is provided inside the housing 10, the container mechanism 30 for containing the battery 100. The container mechanism 30 is disposed, at a substantial center, in the front-rear direction of the housing 10, and the container mechanism 30 is positioned directly below the upper surface opening 13.

An inverter unit 80 is provided, on the rear of the container mechanism 30, in a front-rear direction of the housing 10. The inverter unit 80 includes an inverter 82 and a shroud 90. The inverter 82 functions as a so-called DC-AC inverter, in which the inverter 82 converts DC power supplied from the battery 100 in accordance with an operation of a user, and the inverter 82 outputs AC power.

The inverter 82 includes a rectangular substrate 84 on which predetermined electrical components 86 are mounted on both surfaces. The substrate 84 is disposed so that each flat surface faces a front-rear direction of the housing 10. The electrical components 86 form a predetermined electrical circuit, such as an inverter circuit or a convertor circuit. Another electrical operation portion is mounted on the substrate 84, the other electrical operation portion being an AC-DC converter, a DC-DC converter or the like. Accordingly, it is possible for the inverter 82 to convert, for example, DC power supplied from the battery 100, and it is possible for the inverter 82 to output DC power of a different voltage.

As stated above, the container device 1 has AC power or DC power that is supplied from a power generating device outside the container device 1, via the terminal unit 24. AC power input to the container device 1 is converted into DC power by the AC-DC converter included in the inverter 82, and this DC power is charged into the battery 100. DC power input to the container device 1 converts a voltage by the DC-DC converter included in the inverter 82, and this voltage is charged into the battery 100.

The shroud 90 is a covering member that covers the inverter 82 from the rear, in a front-rear direction of the housing 10. A plurality of air blowers 92 is provided on the shroud 90, the plurality of air blowers 92 cooling the battery 100 and the inverter 82.

The inverter unit 80 is fixed to the inside of the housing 10, by having an upper edge of the substrate 84 supported by an upper edge support member 87, and having a lower edge of the substrate 84 supported by a lower edge support member 88. The upper edge support member 87 is a linear member curved in a U-shape toward the rear, in a front-rear direction of the housing 10. The upper edge support member 87 has both ends that are fixed to the container mechanism 30, and the upper edge support member 87 supports the substrate 84 and the inverter unit 80 by coming into contact with the substrate 84 at two locations positioned at a substantial center in a longitudinal direction (FIG. 16).

The lower edge support member 88 is provided on the lower surface panel 14, and the lower edge support member 88 is a linear member extending along a left-right direction of the housing 10. The lower edge support member 88 is formed curved in a substantially M-shape, in a view from a front surface side of the housing 10, and the lower edge support member 88 supports the substrate 84 and the inverter unit 80 by having two apex portions come into contact with the substrate 84, the two apex portions protruding toward the upside of the housing 10. According to this, the inverter unit 80 is fixed to the housing 10. The upper edge support member 87 and the lower edge support member 88 each correspond to “another support member” in the present disclosure. The inverter unit 80 corresponds to an “electrical operation portion” in the present disclosure.

As shown in FIG. 3 and FIG. 4, the inverter unit 80 is covered from the rear, by the rear surface panel 18. The inverter unit 80 is disposed at a position where a portion positioned on a rear side overlaps an edge portion of the rear surface panel 18, in a view from a left-right direction. According to this, in the container device 1, the inverter unit 80 can be contained with good space efficiency, in a front-rear direction of the container device 1. Accordingly, in the container device 1, it is possible to suppress an increase of a length dimension in a front-rear direction.

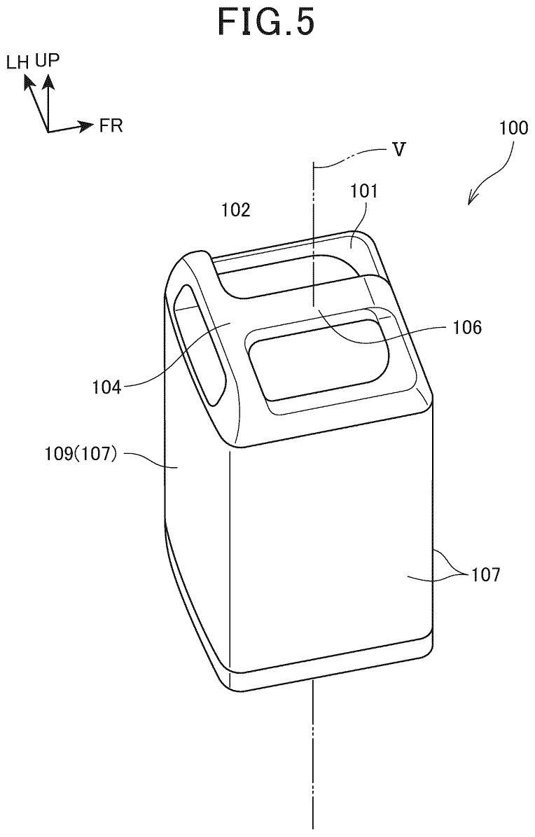

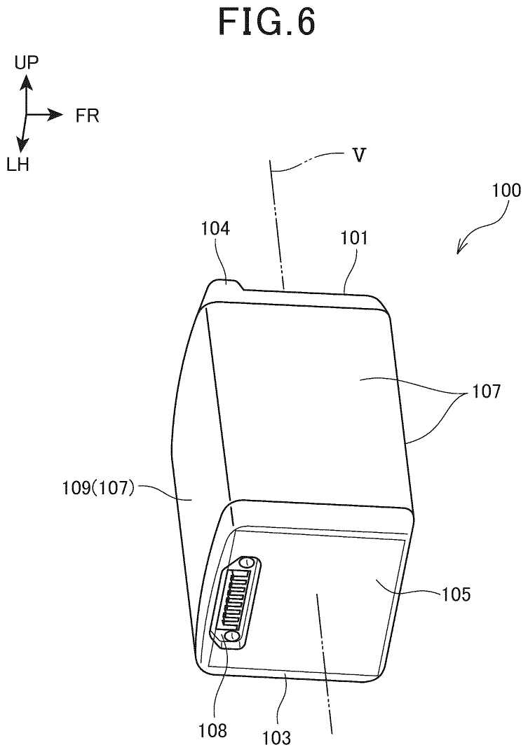

FIG. 5 is a perspective view in which the battery 100 is seen from above. FIG. 6 is a perspective view in which the battery 100 is seen from below. In FIG. 4 and FIG. 5, for convenience of the description, a virtual line V is shown by a two-dot chain line through the center in a planar view of the battery 100, the virtual line V extending along a longitudinal direction of the battery 100. As shown in FIG. 5 and FIG. 6, the battery 100 is a substantially rectangular parallelepiped electrical storage device in which an energy storage unit such as a battery cell is stored inside, the substantially rectangular parallelepiped electrical storage device being portable. Each of a pair of end surfaces 101, 103 positioned in a longitudinal direction of the battery 100 are rectangular in a planar view. The battery 100 corresponds to a “contained item”.

The battery 100 has a battery handle 102 that is provided on the one end surface 101 in a longitudinal direction, the battery handle 102 capable of being held by a user. The battery handle 102 is formed by a side handle portion 104 and a center handle portion 106, the side handle portion 104 extending along one side of the one end surface 101 and the center handle portion 106 extending from a substantial center of the side handle portion 104 in a longitudinal direction to a side positioned on an opposite side, and the battery handle 102 is formed in a substantially T-shape in a planar view.

As shown in FIG. 6, a battery terminal 108 is provided on the other end surface 103. The battery terminal 108 is a female-shaped terminal provided at a position in the vicinity of one side, on the end surface 103, the female-shaped terminal extending along this side. The side of the end surface 103 on which the battery terminal 108 is disposed in the vicinity overlaps the side of the end surface 101 on which the side handle portion 104 is provided, in a planar view in a longitudinal direction of the battery 100. A protruding surface portion 105 is provided at a substantial center of the end surface 103, the protruding surface portion 105 protruding more to the outside than a circumferential edge of the end surface 103. The protruding surface portion 105 is formed in a substantially rectangular shape in a planar view, and the protruding surface portion 105 has a protruding end that is formed on a flat surface.

The battery 100 includes four battery side surfaces 107 extending along a longitudinal direction of the battery 100, both ends of each of the four battery side surfaces 107 being coupled to the end surfaces 101, 103 in a longitudinal direction. From among these battery side surfaces 107, one of the battery side surfaces 107 is formed in a curved surface shape, along a direction orthogonal to a longitudinal direction of the battery 100, in a view from a longitudinal direction of the battery 100, the curved surface shape being bent so as to draw a curved line. In contrast to this, the other battery side surfaces 107 are formed in a substantially flat shape. Namely, the battery 100 is formed in a rotationally asymmetrical shape with the virtual line V set as an axis of rotation. Hereinafter, the battery side surface 107 formed in a curved surface shape is set as a curved surface 109. The curved surface 109 is coupled to a side of the end surface 103 on which the battery terminal 108 is disposed in the vicinity, and the curved surface 109 is coupled to a side of the end surface 101 on which the side handle portion 104 is provided.

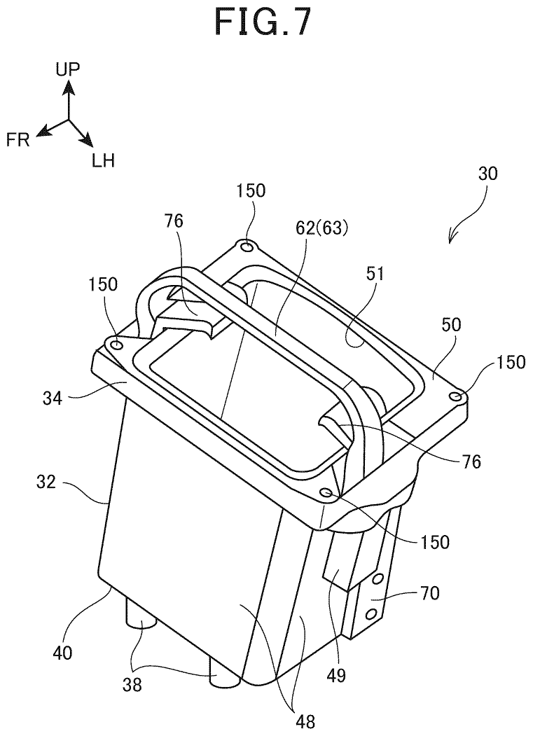

FIG. 7 is a perspective view in which the container mechanism 30 is seen from above. As shown in FIG. 7, the container mechanism 30 contains the battery 100, and the container mechanism 30 is electrically connected to the battery terminal 108 of the battery 100. The container mechanism 30 includes a battery case 32. The battery case 32 is a container made of resin, for example, the battery case 32 containing and holding the battery 100. The battery case 32 is formed in a substantially rectangular parallelepiped shape in which a longitudinal direction extends along an up-down direction of the housing 10.

The battery case 32 includes a back portion 40 forming a bottom surface on the inside of the battery case 32, and the battery case 32 includes side walls 48 erected from each side of the back portion 40. The back portion 40 is positioned on a lower portion side of the housing 10, and the back portion 40 corresponds to a lower end portion of the battery case 32. The back portion 40 is formed in a substantially rectangular shape in a planar view. Each of the side walls 48 forms each of the side surfaces of the battery case 32. Each of the side walls 48 is formed in a substantially rectangular shape in a planar view, and a longitudinal direction of each the side walls 48 extends along an up-down direction of the housing 10. In the present embodiment, a length dimension of the side walls 48 in a longitudinal direction is formed so as to be substantially the same as a length dimension of the battery side surface 107 in a longitudinal direction.

The battery case 32 includes a rectangular insertion/removal slot 31 on which the entire upper end surface is opened. The insertion/removal slot 31 is disposed at a position overlapping the upper surface opening 13, in a planar view of the housing 10. The battery case 32 corresponds to a “container portion” in the present disclosure, and the insertion/removal slot 31 corresponds to a “first opening” in the present disclosure.

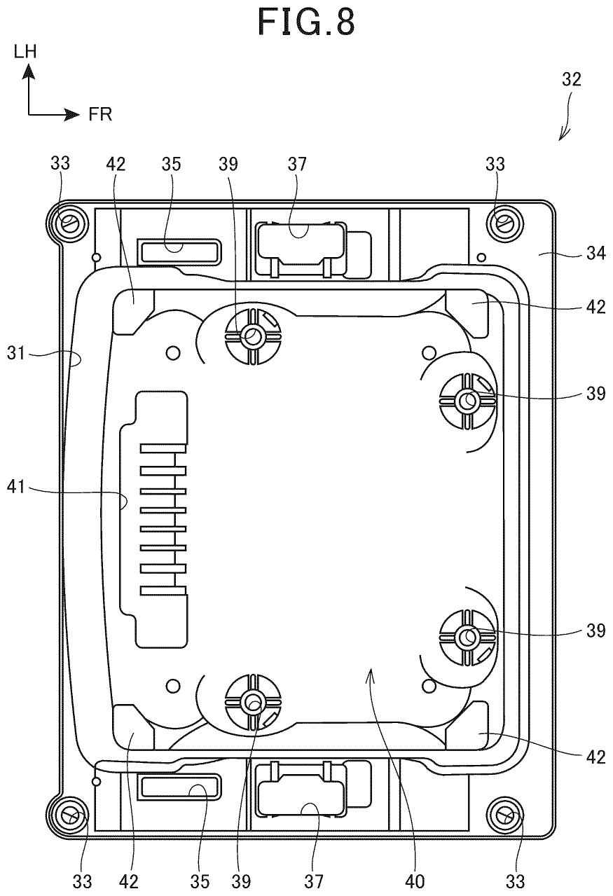

FIG. 8 is a planar view of the battery case 32. As shown in FIG. 8, a frame shaped projecting portion 34 is provided, on a circumferential edge of the insertion/removal slot 31, on the battery case 32, the frame shaped projecting portion 34 projecting to the outside in a predetermined width direction. The frame shaped projecting portion 34 is formed in a rectangular frame shape, in a planar view. A screw hole 33 is provided at each corner portion of the frame shaped projecting portion 34. A plate insertion hole 35 and a metal fitting insertion hole 37 are provided, at portions positioned in a left-right direction of the housing 10 across the insertion/removal slot 31, on the frame shaped projecting portion 34, the plate insertion hole 35 and the metal fitting insertion hole 37 both being a through hole.

The battery case 32 includes a rectangular back portion 40 in a planar view on an opposite side of the insertion/removal slot 31 in a longitudinal direction. A terminal hole 41 is provided on the back portion 40, the terminal hole 41 being a through hole passing through the inside and outside of the battery case 32. The terminal hole 41 is a long hole extending along one side positioned on a rear side of the housing 10, on the back portion 40.

As shown in FIG. 8, a buffering material 42 is provided, at each corner portion of the back portion 40, on the inside of the battery case 32. The buffering material 42 is formed separate from the battery case 32. The buffering material 42 is formed, for example, by a material such as a rubber material, the material having a larger elasticity or a lower hardness than the battery case 32. From among these buffering materials 42, the terminal hole 41 is provided between a pair of the buffering materials 42 provided at each corner portion positioned on a rear side of the housing 10.

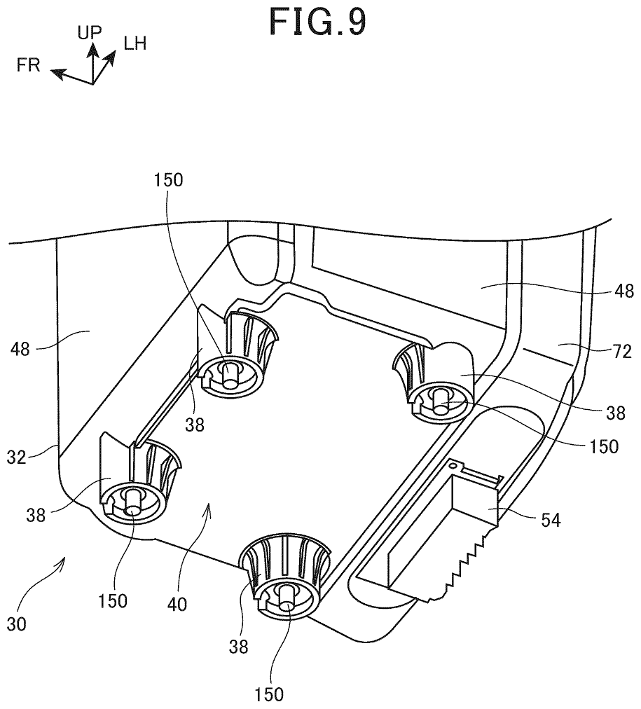

FIG. 9 is a perspective view in which the back portion 40 of the battery case 32 is seen from below the container mechanism 30. As shown in FIG. 9, a plurality of case side bosses 38 is provided on the back portion 40 of the battery case 32, the plurality of case side bosses 38 protruding toward the outside of the battery case 32, and the plurality of case side bosses 38 protruding toward a lower portion side of the housing 10. Each of the case side bosses 38 has a tip end surface that is formed in a circular column shape. A screw hole 39 is provided, along an extending direction of the case side bosses 38, in a substantial center in a planar view of each of the case side bosses 38, the screw hole 39 being a through hole.

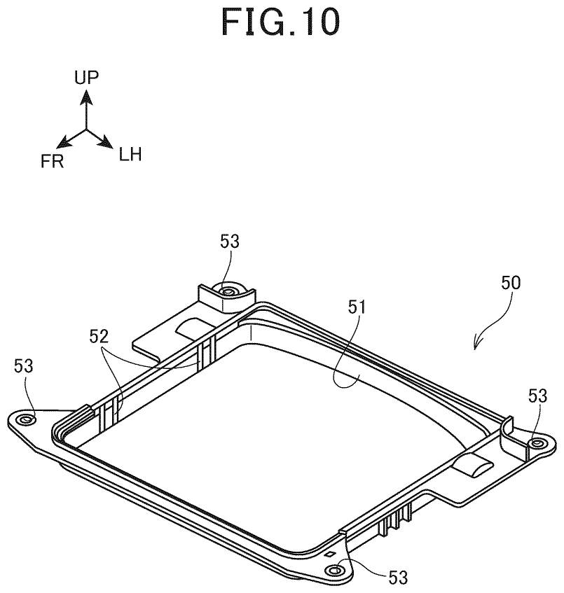

FIG. 10 is a perspective view of the case frame body 50. The case frame body 50 is provided on the battery case 32, the case frame body 50 being a rectangular frame shaped member in a planar view. The case frame body 50 is formed, for example, by a material such as a metallic material, the material including at least either a higher strength than the battery case 32 or a higher rigidity than the battery case 32. Note that, the case frame body 50 may be formed by a material the same as a material of the battery case 32. A frame body opening 51 is provided at the center of the case frame body 50. The frame body opening 51 is formed in a substantially same shape as a shape of a circumferential surface of the battery 100 seen from a longitudinal direction in a planar view. Accordingly, in the frame body opening 51, a side positioned on a rear side of the housing 10 is formed in a curved shape in a planar view, and the other sides are formed in a substantially linear shape.

Note that, a length dimension of each side included in each of the upper surface opening 13 and the insertion/removal slot 31 is formed so as to become greater than or equal to the length dimension of each side of the frame body opening 51.

A protruding portion 52 is provided, from each side of the frame body opening 51, on the case frame body 50, the protruding portion 52 protruding in a predetermined dimension toward the center of the frame body opening 51. The protruding portion 52 is provided on each of the sides positioned in a left-right direction of the housing 10, on the frame body opening 51.

A screw hole 53 is provided on each corner portion of the case frame body 50. The case frame body 50 is attached to the battery case 32, by having each of the screw holes 53 and each of the screw holes 33 fastened together by the fastening member 150, in a state where each of the screw holes 53 and each of the screw holes 33 are mutually overlapping. The case frame body 50 corresponds to “another frame portion”.

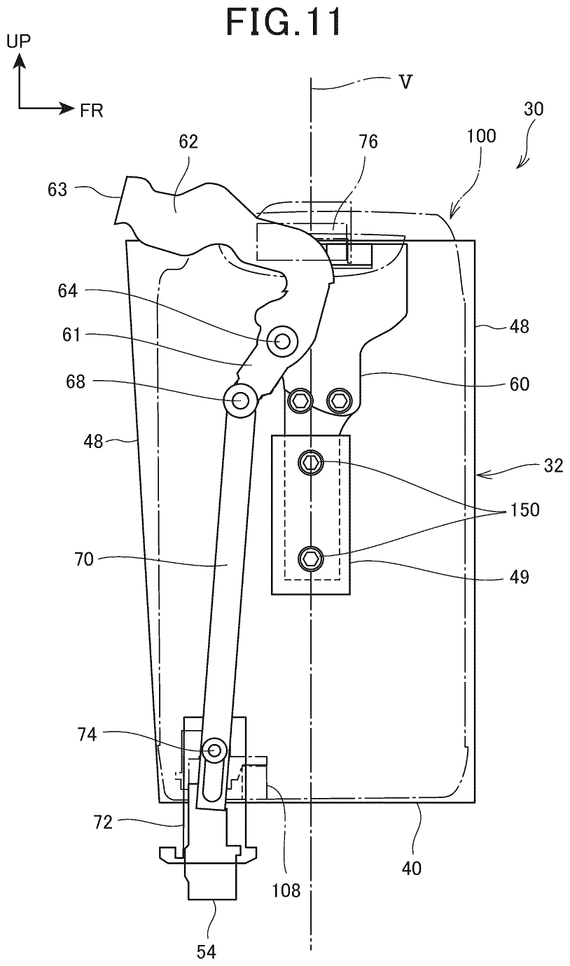

FIG. 11 and FIG. 12 are each a schematic view in which the container mechanism 30 is seen from a right direction of the container device 1. In FIG. 11 and FIG. 12, for convenience of the description, the battery 100 and a lock mechanism 76 are shown by a one-dot chain line, and a virtual line V is shown by a two-dot chain line, the virtual line V extending along a longitudinal direction of the battery 100, through the center of the battery 100 in a planar view. A pocket shaped metal fitting holding portion 49 is provided on each of the side walls 48 positioned on the left and right of the battery case 32, the pocket shaped metal fitting holding portion 49 having a space provided on the inside. An upper end of the metal fitting holding portion 49 is coupled to the metal fitting insertion hole 37.

A mounting metal fitting 60 is stored, via the metal fitting insertion hole 37, in each of the metal fitting holding portions 49. The mounting metal fitting 60 is a plate shaped member extending along an up-down direction of the housing 10. A lower portion side of each of the mounting metal fittings 60 is stored on the inside of the metal fitting holding portion 49, and the lower portion side of each of the mounting metal fittings 60 is fixed to the battery case 32 by the fastening member 150 inserted from outside the metal fitting holding portion 49. The upper end of each of the mounting metal fittings 60 is disposed more upward than the insertion/removal slot 31.

Each of the mounting metal fittings 60 rotatably supports a holding handle 62 along a front-rear direction of the housing 10. The holding handle 62 is a linear member included to extend along a left-right direction of the housing 10. The holding handle 62 is formed in a substantially U shape seen from the front of the housing 10, and both sides of the holding handle 62 in a longitudinal direction are rotatably attached to each of the mounting metal fittings 60, via a metal fitting shaft body 64. A lock plate 63 is disposed more upward than the insertion/removal slot 31 on a substantial center of the holding handle 62, the lock plate 63 extending linearly. The lock plate 63 is formed to enable the lock plate 63 to be held by a user. A link coupling end 61 is provided on both ends of the holding handle 62, the link coupling end 61 extending from the metal fitting shaft body 64 toward a rear side of the housing 10.

One end portion of a link plate 70 in a longitudinal direction is rotatably coupled, via the link shaft body 68, to a tip end of each of the link coupling ends 61. The link plate 70 is a plate shaped member extending along an up-down direction of the housing 10, outside of each of the side walls 48 positioned on the left and right. Each of the link plates 70 is inserted into the plate insertion hole 35.

Both ends of a terminal holding plate 72 in a longitudinal direction are rotatably coupled, via the plate shaft body 74, to each of the other end portions at which each of the link plates 70 are included. The terminal holding plate 72 is a plate shaped member including a predetermined length dimension. The terminal holding plate 72 is disposed along a lower portion of one of the side walls 48 at which one end portion in a longitudinal direction is positioned in a left-right direction. The terminal holding plate 72 is disposed along a lower portion of the one side wall 48 at which the other end portion is positioned in a left-right direction, through a lower side of the back portion 40 and the terminal hole 41 from a lower portion of the one side wall 48. Accordingly, the terminal holding plate 72 is formed folded in a substantially U shape in a front view of the housing 10.

A case side connection terminal 54 is provided, at a position opposite the terminal hole 41, on the terminal holding plate 72. The case side connection terminal 54 is a male-shaped terminal formed to be connectable to the battery terminal 108. The case side connection terminal 54 can be inserted into the terminal hole 41. The case side connection terminal 54 is electrically connected to the inverter 82 via predetermined wiring. Accordingly, when the case side connection terminal 54 is connected to the battery terminal 108, electrical power stored in the battery 100 is supplied to the inverter 82.

As shown in FIG. 3, the battery case 32 and the case side connection terminal 54 are disposed in an inside space of the container device 1, the battery case 32 and the case side connection terminal 54 being disposed lined up along an up-down direction. The case side connection terminal 54 is disposed at a position overlapping an edge portion of the lower surface panel 14, in a view from a left-right direction. According to this, in the container device 1, the battery case 32 and the case side connection terminal 54 can be contained with good space efficiency, in an up-down direction of the container device 1. Accordingly, in the container device 1, it is possible to suppress an increase of a height dimension in an up-down direction. The case side connection terminal 54 corresponds to a “connection portion”.

As shown in FIG. 11, in the case where the lock plate 63 of the holding handle 62 moves to a rear side with respect to the insertion/removal slot 31, each of the link coupling ends 61 moves to a lower portion side of the housing 10, and each of the link plates 70 and the terminal holding plate 72 move downward. According to this, the case side connection terminal 54 moves to the outside of the battery case 32, and the case side connection terminal 54 moves downward.

As shown in FIG. 12, in the case where the lock plate 63 of the holding handle 62 is moved to an upper side with respect to the insertion/removal slot 31, each of the link coupling ends 61 moves to an upper side of the housing 10, and each of the link plates 70 and the terminal holding plate 72 move upward. According to this, the case side connection terminal 54 moves to the inside of the battery case 32, through the terminal hole 41.

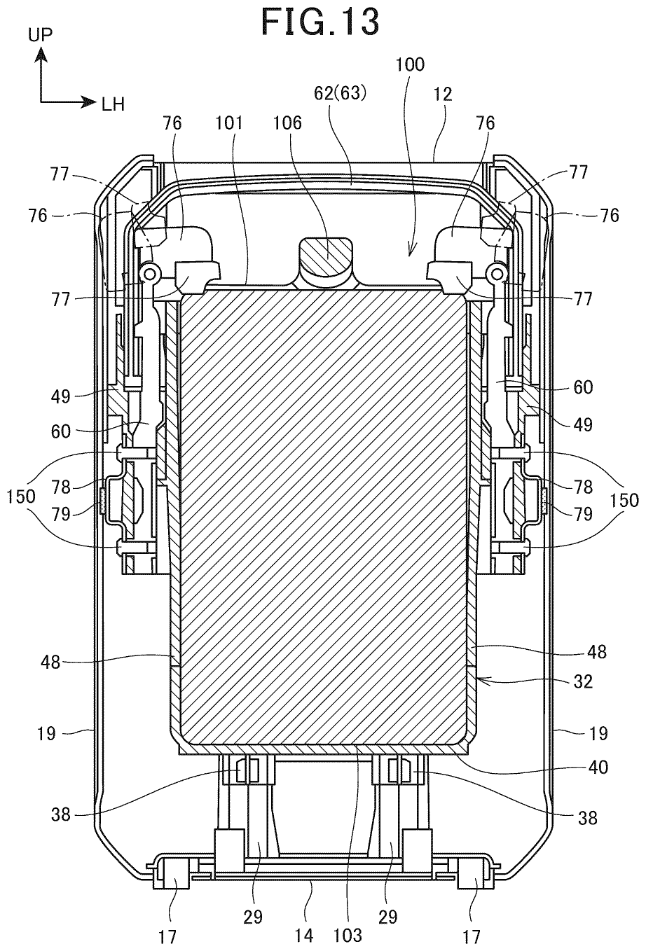

FIG. 13 is a longitudinal cross-section view in which the container device 1 is cut at Plane XIII shown in FIG. 1. Plane XIII is a flat surface through the mounting metal fitting 60. In FIG. 13, for convenience of the description, a lock mechanism 76 in the case where rotating toward the outside of the insertion/removal slot 31 is shown by a one-dot chain line. As shown in FIG. 13, the lock mechanism 76 is provided on an upper end of each of the mounting metal fittings 60. Each of the lock mechanisms 76 is rotatably attached along a left-right direction of the housing 10, on an upper end of the mounting metal fitting 60.

The lock mechanism 76 is positioned more on the insertion/removal slot 31 side than both ends of the holding handle 62. In the case where the lock plate 63 of the holding handle 62 is moved to an upper side with respect to the insertion/removal slot 31, each of the lock mechanisms 76 has rotation that is restricted, by each of both ends of the holding handle 62, so that each of the lock mechanisms 76 becomes a position on the inside of the insertion/removal slot 31. Each of the lock mechanisms 76 includes a pressing portion 77. The pressing portion 77 is formed, for example, by a material such as a rubber material, the material having a larger elasticity or a lower hardness.

A contacting body 78 is provided, on each of the side walls 48, in the battery case 32, the side walls 48 being disposed along a left-right direction of the housing 10. The contacting body 78 is a member formed by folding a linear metallic material in a U-shape. Each of the contacting bodies 78 is provided so that a U-shaped apex portion extends toward each of the inner side surfaces of the side surface panels 19 positioned on the left and right. A buffering body 79 is provided, at the U-shaped apex portion, on each of the contacting bodies 78. The buffering body 79 is formed, for example, by a material such as a rubber material, the material having a larger elasticity or a lower hardness. Each of the buffering bodies 79 makes contact with each of the inner side surfaces of the side surface panels 19 positioned on the left and right.

According to this, the side surface panels 19 positioned on the left and right are supported by the battery case 32, via the contacting bodies 78. Accordingly, in the container device 1, in the case where the container device 1 is installed in the second posture in which one of the side surface panels 19 positioned on the left and right is installed as a bottom surface, the container device 1 can suppress deformation of the side surface panel 19, and the container device 1 can be stably installed. Moreover, in this case, the other one of the side surface panels 19 is supported by the battery case 32, via the contacting body 78, the other one of the side surface panels 19 being a roof surface. Accordingly, in the container device 1, in the case where the container device 1 is installed in the second posture in which one of the side surface panels 19 positioned on the left and right is installed as a bottom surface, deformation of both of the side surface panels 19 can be suppressed. In this second posture, one of the side surface panels 19 is disposed in a vertical direction, in an up-down direction of the housing 10. The contacting body 78 corresponds to a “projecting portion”.

Note that, each of the contacting bodies 78 is fixed to each of the side walls 48 of the battery case 32, by having both ends fastened together, by the fastening member 150 for fixing the mounting metal fitting 60 to the metal fitting holding portion 49. According to this, in the container device 1, each of the contacting bodies 78 can be provided, while suppressing an increase in the number of components. Moreover, the contacting body 78 is not limited to the battery case 32, and the contacting body 78 may be provided so as to come into contact with the battery case 32 from each of the left and right side surface panels 19. Moreover, for example, a coupling member may be provided, instead of the contacting body 78, in the container device 1, the coupling member for coupling each of the left and right side surface panels 19 and the battery case 32.

Here, a fixing structure of the housing 10 and the battery case 32 will be described. A plurality of panel side bosses 29 is provided on the lower surface panel 14, the plurality of panel side bosses 29 protruding toward the upside of the housing 10. Each of the panel side bosses 29 has a tip end surface that is formed in a circular column shape. Each of the panel side bosses 29 is disposed at a position corresponding to each of the case side bosses 38 in a planar view of the housing 10. Each of the panel side bosses 29 and each of the case side bosses 38 are fixed to one another, by coupling each of the panel side bosses 29 and each of the case side bosses 38 by the fastening member 150 inserted into the screw hole 39, in a state where the tip end surfaces abut on one another. According to this, the lower surface panel 14 and the battery case 32 are coupled, and the battery case 32 is disposed at a predetermined position, in an up-down direction of the housing 10.

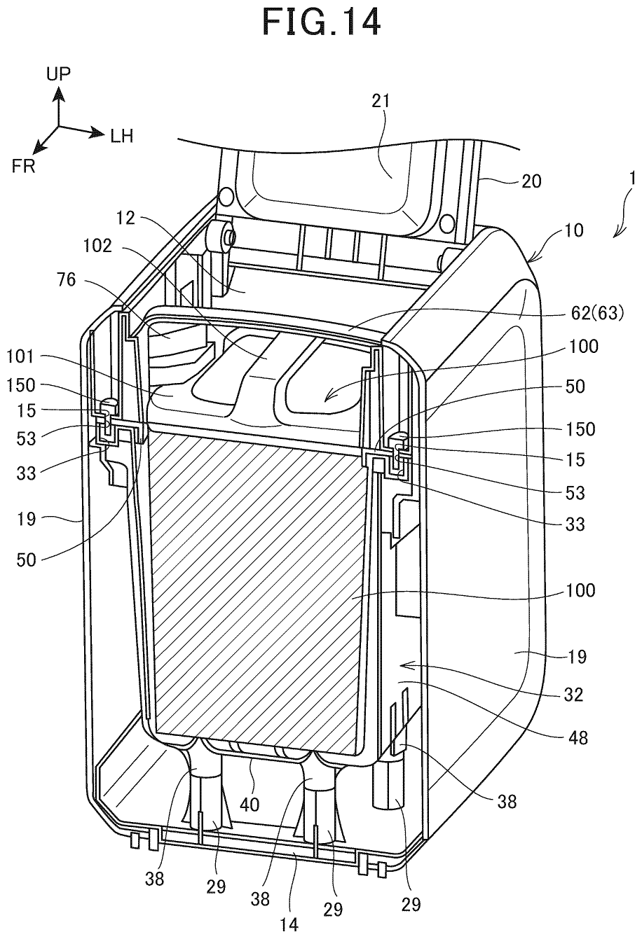

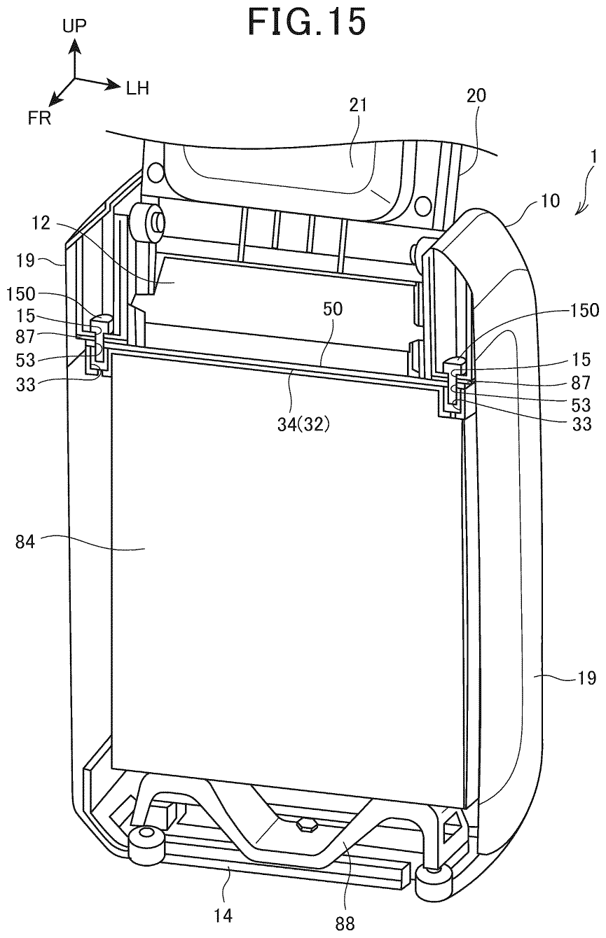

FIG. 14 is a longitudinal cross-section view in which the container device 1 is cut at Plane XIV shown in FIG. 1. Plane XIV is a flat surface through the screw hole 15 positioned on a front surface side of the housing 10. FIG. 15 is a longitudinal cross-section view in which the container device 1 is cut at Plane XV shown in FIG. 1. Plane XV is a flat surface through the screw hole 15 positioned on a rear surface side of the housing 10. As shown in FIG. 14 and FIG. 15, the upper surface panel 12 and the battery case 32 are disposed so that each of the screw holes 15 and each of the screw holes 33 overlap in a planar view of the housing 10. In this state, the upper surface panel 12 and the battery case 32 are fixed, by having the fastening member 150 screwed into each of the screw holes 15 and each of the screw holes 33.

According to this, in the container device 1, the upper surface panel 12 and the lower surface panel 14 are coupled by the battery case 32. Accordingly, an improvement of the strength of the housing 10 can be performed.

As stated above, attachment to the battery case 32 is performed, by having the screw holes 53 of the case frame body 50 fastened together to each of the screw holes 33 by the fastening member 150. In addition, attachment to the battery case 32 is performed, by having both ends of the upper edge support member 87 fastened together to each of the screw holes 33 positioned on a rear side of the housing 10, by the fastening member 150. According to this, in the container device 1, the upper surface panel 12, the battery case 32, the case frame body 50, and the upper edge support member 87 can be coupled, while suppressing an increase in the number of components.

In this way, in the container device 1 for which an increase in the strength of the housing 10 is performed, the container device 1 is not limited to the first posture, in which the container device 1 is installed with a lower surface as a bottom surface in contact with an installation surface, and the container device 1 can be installed with either an upper surface or a rear surface as a bottom surface. In addition, the container device 1 can be installed in the second posture in which one of the left and right side surfaces is set as a bottom surface. According to this, it is possible for the container device 1 to change an installation posture, in accordance with a usage of a user.

FIG. 16 and FIG. 17 are each a perspective view showing an assembly structure of the container device 1. Next, an assembly procedure of the container device 1 will be described. As shown in FIG. 16, in the case where assembling the container device 1, first, the container mechanism 30 is fixed to the lower surface panel 14. Next, the front surface panel 16 and the inverter unit 80 are attached to the lower surface panel 14. In this case, the front surface panel 16 is attached to the lower surface panel 14, in a state where the user interface unit 22, the terminal unit 24, and the communication unit 120 are attached beforehand. According to this, the front surface panel 16 and the inverter unit 80 are fixed to the lower surface panel 14, the front surface panel 16 including multiple electrical components of the container device 1. Accordingly, in the container device 1, for example, wiring work can be easily performed, the wiring work being linking the user interface unit 22, the terminal unit 24, and the inverter unit 80 by a connection cable 145 or the like. In addition, in the container device 1, various types of wiring can be routed with better efficiency, the various types of wiring being the connection cable 145 or the like. As shown in FIG. 17, in the container device 1, the front surface panel 16 and the inverter unit 80 are fixed to the lower surface panel 14, and thereafter the upper surface panel 12 and the rear surface panel 18 are attached.

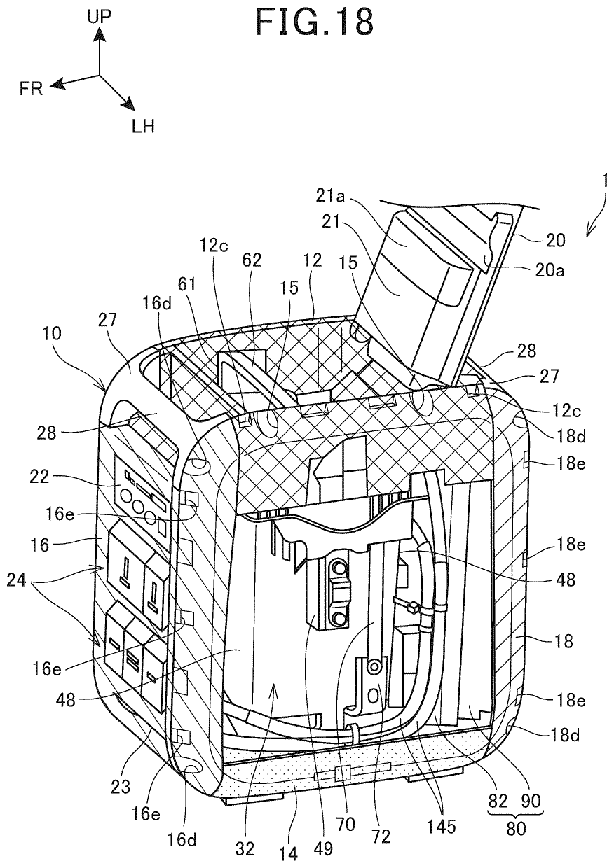

FIG. 18 is a perspective view in which the container device 1 is seen from the left side. In FIG. 18, the side surface panel 19 forming a left side surface is omitted. In FIG. 18, for convenience of the description, hatching is attached to each of the upper surface panel 12, the lower surface panel 14, the front surface panel 16, and the rear surface panel 18. As shown in FIG. 18, the upper surface panel 12, the lower surface panel 14, the front surface panel 16, and the rear surface panel 18 attached in such a way are coupled to one another so as to become a rectangular frame shape, in a view from a left-right direction of the housing 10, the rectangular frame shape surrounding the members contained in the housing 10, such as the container mechanism 30 and the inverter unit 80. Accordingly, each panel reinforces one another, and it is possible to perform an increase in the strength of the container device 1.

In this way, in the container device 1, a frame portion is formed by the four members of the upper surface panel 12, the lower surface panel 14, the front surface panel 16, and the rear surface panel 18. According to this, in the container device 1, the frame portion can be formed more easily than the case where the frame portion is formed by a single member. Accordingly, the container device 1 becomes easy to manufacture.

In addition, since the front surface panel 16 and the rear surface panel 18 are fixed to the upper surface panel 12 and the lower surface panel 14, the handles 28 being provided on the front surface panel 16 and the rear surface panel 18, the strength of the container device 1 is secured in the case where a user transports the container device 1 by the user holding the handles 28. In addition, as stated above, in the container device 1, the upper surface panel 12 and the lower surface panel 14 are coupled by the battery case 32. Accordingly, an improvement of the strength of the housing 10 can be performed.

Note that, the present invention is not limited to the above description, and in the case where assembling the container device 1, the upper surface panel 12 and the lower surface panel 14 may be attached to the container mechanism 30, and thereafter the front surface panel 16 and the rear surface panel 18 may be fixed to the upper surface panel 12 and the lower surface panel 14.

FIG. 19 is a side surface view in which the container device 1 is seen from the right side. In FIG. 19, the side surface panel 19 forming a right side surface is omitted. In FIG. 19, for convenience of the description, hatching is attached to each of the upper surface panel 12, the lower surface panel 14, the front surface panel 16, and the rear surface panel 18. Here, the communication unit 120 will be described in detail. As stated above, the communication unit 120 is attached to the terminal unit 24. The communication unit 120 includes communication hardware compliant with short-range wireless communication standards, such as an antenna 122 or a communication circuit. It is possible for the communication unit 120 to communicate, for example, with a terminal device such as a remote control, a smartphone, or a tablet. Note that, Wi-Fi (Registered Trademark) and Bluetooth (Registered Trademark) are provided, in this example, as short-range wireless communication standards. The communication unit 120 is attached to the side of the terminal unit 24, and the communication unit 120 is provided at a position of the housing 10 not exposed to the outside.

In the present embodiment, the communication unit 120 is attached to the terminal unit 24, by the fastening member 150. This fastening member 150 is attached so that a screw head included in the fastening member 150 faces the side surface panel 19 forming a right side surface of the housing 10. Moreover, the communication unit 120 and the fastening member 150 are each disposed at a position exposed to the outside, in the case where the side surface panel 19 is removed.

The communication unit 120 disposed in such a way has a front that is covered by the front surface panel 16, which is a resin material. In the communication unit 120 disposed in such a way, an antenna 122 is disposed on a front surface side and an upper portion side of the container device 1.

In the case where a user uses the container device 1 via the terminal device, it is assumed that the user interface unit 22 and the terminal unit 24 are operated together. In the present embodiment, the communication unit 120 and the antenna 122 are each disposed at a position in the vicinity of the front surface panel 16, and in addition, members are not disposed on a front surface side of the antenna 122, so that the members become a shield. According to this, in the container device 1, an operation using the terminal device can be easily performed. In addition, in the container device 1, communication with the terminal device being hindered is suppressed.

A communication unit terminal 120a is provided in the communication unit 120, the communication unit terminal 120a being capable of connecting a terminal of predetermined wiring or the like. The communication unit terminal 120a is a female-shaped terminal provided so as to be opened toward the rear of the housing 10, along a front-rear direction of the housing 10. Note that, the present invention is not limited to this, and the communication unit terminal 120a may be a male-shaped terminal provided so as to protrude toward the rear of the housing 10, along a front-rear direction of the housing 10.

An activation battery 98 is provided, on one of the side walls 48 disposed along a left-right direction of the housing 10, on the battery case 32. The activation battery 98 is an electrical storage device for supplying electrical power to a processor or various types of electrical components for performing control of the container device 1. When an operator for activating the container device 1 is operated, this activation battery 98 supplies electrical power to the processor, and the container device 1 is driven by having this processor start control of the container device 1. The activation battery 98 supplies electrical power with a voltage lower than a voltage of the battery 100.

The activation battery 98 is attached to the battery case 32 via a fixing bracket 96. The fixing bracket 96 is fixed to each of the side walls 48 of the battery case 32, by having the fixing bracket 96 fastened together to the metal fitting holding portion 49, by the fastening member 150 for fixing the mounting metal fitting 60 to the metal fitting holding portion 49. The activation battery 98 is fixed to the fixing bracket 96 by the fastening member 150 such as a screw member. A bracket buffering material 96a is provided, at a predetermined portion of a surface opposite the battery case 32, on the activation battery 98. The bracket buffering material 96a is formed by a material that includes flexibility such as a rubber material or a sponge material. The fixing bracket 96 comes into contact with the battery case 32 via this bracket buffering material 96a. Accordingly, in the case where transporting the container device 1, or in the case where performing insertion or removal of the battery 100 with respect to the container device 1, the activation battery 98 being vibrated is suppressed, by the bracket buffering material 96a, even in the case where the housing 10 vibrates. In the container device 1, the activation battery 98 is disposed between one of the side walls 48 and one of the side surface panels 19, and in the case where the side surface panel 19 is removed, the activation battery 98 is disposed at a position exposed to the outside.

An activation battery terminal 98a is provided on the activation battery 98, the activation battery terminal 98a being capable of connecting a terminal of a predetermined wiring or the like. The activation battery terminal 98a is a female-shaped terminal provided so as to be opened toward the downside of the housing 10, along an up-down direction of the housing 10. Note that, the present invention is not limited to this, and the activation battery terminal 98a may be a male-shaped terminal provided so as to protrude toward the downside of the housing 10, along an up-down direction of the housing 10.

A connection cable 145 is connected to both the communication unit terminal 120a and the activation battery terminal 98a. The connection cable 145 extends toward the rear of the housing 10, along the lower surface panel 14 of the housing 10, and another end of the connection cable 145 is connected to the inverter unit 80.

As stated above, the communication unit 120 and the activation battery 98 are each disposed at a position exposed to the outside, in the case where the side surface panel 19 is removed. A screw head included in the fastening member 150 is attached so as to face the side surface panel 19 forming a right side surface of the housing 10, the fastening member 150 for fixing each of the communication unit 120 and the activation battery 98. Similarly, the communication unit terminal 120a and the activation battery terminal 98a are each disposed at a position exposed to the outside, in the case where the side surface panel 19 is removed. Accordingly, in the container device 1, by having a user remove one of the side surface panels 19, it is possible for the user to easily perform an operation related to inspection or replacement of the communication unit 120, or it is possible for the user to easily perform an operation related to maintenance such as a wiring connection process of the connection cable 145 or the like. The communication unit 120 corresponds to an “accessory component”, and the activation battery 98 corresponds to an “accessory component, electrical accessory unit”.

### (1.2. Operation)

An operation of the container device 1 configured such as above will be described. In the case where the battery 100 is contained in the container device 1, a user opens the cover body 20, and the user rotates the holding handle 62, so that the lock plate 63 is positioned at a predetermined position on a rear side with respect to the insertion/removal slot 31. According to this, each of the lock mechanisms 76 rotates along a left-right direction of the housing 10, and each of the lock mechanisms 76 moves to the outside of the insertion/removal slot 31 in a planar view.

Next, the user holds the battery handle 102, and the user performs insertion into the upper surface opening 13, the frame body opening 51, and the insertion/removal slot 31 from the other end surface 103 side, along the virtual line V. At this time, the user inserts the battery 100 in a posture in which the curved surface 109 is opposite a rear side of the housing 10. As shown in FIG. 10 and FIG. 11, in the case where the battery 100 is attached/detached to/from the container mechanism 30, the attachment/detachment direction becomes a direction along the virtual line V extending along a longitudinal direction of the battery 100, through the center of the battery 100 in a planar view, the attachment/detachment direction being a direction of movement. In other words, the attachment/detachment direction is a direction along a longitudinal direction of the battery 100, and the attachment/detachment direction is a direction along a longitudinal direction of the battery case 32.

As stated above, only the side of the frame body opening 51 positioned on a rear side of the housing 10 is formed so as to be bent in an arc shape. Accordingly, only in the case where the user inserts the battery 100, in a posture in which the curved surface 109 is opposite a rear side of the housing 10, it is possible for the battery 100 to be inserted into the frame body opening 51. In contrast to this, in the case where the user inserts the battery 100 in a different posture to the above-stated posture, the battery 100 cannot pass through the frame body opening 51.

According to this, in the container device 1, the battery terminal 108 and the case side connection terminal 54 being unable to be connected is suppressed, namely, the battery 100 being contained in a posture in which the battery 100 is unable to be electrically connected to the container device 1 is suppressed. Accordingly, in the container device 1, a connection defect of the container device 1 and the battery 100 occurring can be suppressed.

As stated above, each of the buffering materials 42 protrudes from each of the back portion 40 and the side walls 48, on the inside of the battery case 32. Accordingly, when the battery 100 is inserted into the battery case 32 until the end surface 103 come into contact with the back portion 40, each of the buffering materials 42 makes contact with the end surface 103 and each of the battery side surfaces 107. Each of the buffering materials 42 is elastically deformed by the weight of the battery 100. According to this, the battery 100 is stored in the battery case 32. In this way, in the container device 1, by having the buffering material 42 provided, it is possible to suppress the end surface 103 from strongly making contact with the back portion 40, and it is possible to suppress wear of the battery 100 and battery case 32, at the time of insertion of the battery 100.

The battery 100 stored in the battery case 32 has only the end surface 101 positioned more upward than the insertion/removal slot 31. In other words, the battery 100 stored in the battery case 32 has the end surface 101 and the battery handle 102 exposed from the battery case 32.

When the battery 100 is stored in the battery case 32, the user rotates the holding handle 62, until the lock plate 63 is positioned at a predetermined position above the insertion/removal slot 31, such as shown in FIG. 13. In accordance with this rotation of the holding handle 62, each of the lock mechanisms 76 rotates along a left-right direction of the housing 10, each of the lock mechanisms 76 moves to the inside of the insertion/removal slot 31 in a planar view, and each of the pressing portions 77 comes into contact with the end surface 101 of the battery 100. In addition, by rotation of the holding handle 62, the case side connection terminal 54 moves to the inside of the battery case 32, through the terminal hole 41, and the case side connection terminal 54 is connected to the battery terminal 108. According to this, the container device 1 and the battery 100 are electrically connected.

Afterwards, the user rotates the cover body 20 to block the upper surface opening 13. At this time, as shown in FIG. 11, the expanded portion 21 comes into contact with the holding handle 62 from a rear side of the housing 10, and the expanded portion 21 restricts rotation of the holding handle 62. According to this, in the container device 1, the container device 1 and the battery 100 are electrically connected, and thereafter the holding handle 62 being rotated is restricted, even in the case where the container device 1 is disposed in any posture.

On the other hand, in the case where the lock plate 63 is not positioned at a predetermined position above the insertion/removal slot 31, namely, in the case where containment of the battery 100 is not completed by the container mechanism 30, when the cover body 20 is rotated so as to block the upper surface opening 13, a lower surface of the expanded portion 21 comes into contact with the lock plate 63. According to this, the upper surface opening 13 being blocked by the cover body 20 is inhibited. Accordingly, in the container device 1, in the case where containment of the battery 100 is not completed, use starting is suppressed.

As stated above, the holding handle 62 is provided so as to rotate along a front-rear direction of the housing 10, the holding handle 62 extending along a left-right direction of the housing 10.

When the holding handle 62 is rotated until the lock plate 63 moves to an upper side with respect to the insertion/removal slot 31, each of the lock mechanisms 76 has rotation that is restricted by the holding handle 62, and each of the lock mechanisms 76 presses the end surface 101 of the battery 100. According to this, each of the pressing portions 77 elastically deforms to be in close contact with the end surface 101. In contrast to this, the end surface 103 of the battery 100 is held by each of the buffering materials 42, while the end surface 103 is pressed by a repellant force of each of the buffering materials 42. In this way, the battery 100 is contained so as to be sandwiched by each of the lock mechanisms 76 and each of the buffering materials 42, along a longitudinal direction of the battery 100. Accordingly, it is possible for the battery case 32 to more firmly contain the battery 100.

In addition, when the battery 100 is contained in the container mechanism 30, each of the battery side surfaces 107 positioned in a left-right direction of the housing 10, on an upper end side of the battery 100, are disposed at a position in the vicinity of the protruding portion 52 provided on the case frame body 50. According to this, the battery 100 has movement that is restricted along a left-right direction of the housing 10 on the upper end side. Accordingly, in the container device 1, vibrations and positional displacement of the battery 100 can be suppressed, on the end surface 101 side of the battery 100.

As stated above, each of the case frame body 50 and the buffering material 42 is a member with a highest frequency of coming into contact with the battery 100. Since each of the case frame body 50 and the buffering material 42 is formed separate from the battery case 32, in the container device 1, only the case frame body 50 or the buffering material 42 can be easily exchanged, even in the case where deformation or damage occurs in each of the case frame body 50 and the buffering material 42. In addition, in the container device 1, it is possible to manufacture the shape of the case frame body 50 and the shape of buffering material 42 by more finely adjusting these shapes. In addition, since the case frame body 50 is formed by a material including a higher strength or rigidity than a material of the battery case 32, deformation of the case frame body 50 can be suppressed.

The above-stated embodiment exemplifies one aspect of the present invention, and the above-stated embodiment can be arbitrarily modified and applied in a range that does not deviate from the content of the present invention.

For example, while the container device 1 of the present embodiment is an electrical power supply device for supplying electrical power to outside of the device, by making the battery 100 stored inside of the housing 10 a power source, the present invention is not limited to this, and the container device 1 may be an electrical power consuming device including an electrical power consuming portion integrally formed with this device, such as a light source or voice output device.

Moreover, for example, in the above-stated embodiment, while the case frame body 50 is formed separate from the battery case 32, the present invention is not limited to this, and the case frame body 50 may be integrally formed with the battery case 32.

Moreover, for example, the container device 1 may include a seal material for sealing a gap between the container mechanism 30 and the battery 100 to be liquid tight, the battery 100 being contained in the container mechanism 30, and the container device 1 may include a sealing structure formed by this seal material. In this case, the container device 1 may have the cover body 20 omitted.

In the above-stated embodiment, while the battery 100 is formed in a rotationally asymmetrical shape with the virtual line V as an axis of rotation, the present invention is not limited to this, and the battery 100 may be formed in a rotationally symmetrical shape such as a columnar shape. In addition, the battery terminal 108 may be formed so as to have a position and shape in which the battery 100 becomes a rotationally symmetrical shape.

In the above-stated embodiment, while the buffering material 42 is provided, the buffering material 42 may be omitted, and a thickness dimension of the pressing portion 77 may be increased. Moreover, for example, the pressing portion 77 and the buffering material 42 may be formed by the same material.

While the protruding portion 52 is provided on the case frame body 50, the present invention is not limited to this, and the protruding portion 52 may be provided on the battery case 32. The protruding portion 52 may be provided at any position in a longitudinal direction of the battery case 32. Moreover, in this case, the container device 1 may have the case frame body 50 omitted.

In the above-stated embodiment, while the container device 1 and the container mechanism 30 contain the battery 100 including a battery cell inside as an electrical storage device, the present invention is not limited to this, and the container device 1 and the container mechanism 30 may contain another electrical storage device such as a capacitor.

In the above-stated embodiment, the container device 1 contains the battery 100, as a portable energy storage device, the battery 100 storing electrical power. However, the present invention is not limited to this, and the container device 1 may attachably/detachably contain, for example, a fuel cell using hydrogen or the like. Moreover, for example, the container device 1 may include a storage unit of fuel used for power generation, such as a hydrogen container for storing hydrogen used in a fuel cell, or a so-called portable hydrogen tank.

Moreover, for example, the container device 1 may include a combustion engine such as an engine, and the container device 1 may attachably/detachably contain a container for storing liquid fuel such as gasoline combusted in the combustion engine, or the container device 1 may attachably/detachably contain a container for storing gaseous fuel such as hydrogen. In this way, the container device 1 is not limited to a portable energy storage device, and the container device 1 may attachably/detachably contain a container for storing an energy source such as fuel. In this case, the container device 1 includes a mechanism for storing electrical power from an energy source such as hydrogen.

In the above-stated embodiment, while the container device 1 includes a power supply function and a power charging function, the present invention is not limited to this, and the container device 1 may include only a power supply function, or the container device 1 may include only a power charging function.

The directions such as a horizontal direction and a vertical direction, and the various types of shapes, in the above-stated embodiment, include a so-called equivalent range, which accomplishes the same working effect as these directions and shapes, unless otherwise noted.

### (Configurations Supported by the Embodiments)

The above-stated embodiment supports the following configurations.

(Configuration 1) A container device including a housing having six substantially quadrangular surfaces facing mutually different directions, the housing being formed in a substantially polyhedral shape, and a container portion provided inside the housing, the container portion containing a contained item to enable the contained item to be inserted and removed, in which the housing has a first member and a second member, the first member and the second member each being attached to the container portion, and the second member is attached to an opposite side of the first member across the container portion. According to this configuration, the first member and the second member constituting the housing are coupled via the container portion. Accordingly, the strength of the housing is improved.

(Configuration 2) The container device described in Configuration 1, in which a first opening is provided on the container portion, the first opening enabling the contained item to be inserted and removed, and the first member is attached at a position of the container portion corresponding to the first opening, and a second opening is provided, the second opening overlapping the first opening, and the second opening enabling the contained item to be inserted and removed. According to this configuration, the contained item is inserted between the first opening and the second opening, and the contained item is stored in the container portion. Accordingly, the container device can contain the contained item.

(Configuration 3) The container device described in Configuration 2, in which a cover portion is provided on the first member, the cover portion covering at least a part of the second opening to enable the at least a part of the second opening to be opened/closed. According to this configuration, the second opening is blocked by the cover portion. Accordingly, the container device can protect the inside of the housing.

(Configuration 4) The container device according to any one of Configurations 1 to 3, in which the housing is provided to enable the second member to be loaded in a vertical direction lower side posture. According to this configuration, the housing can be installed with the second member as a bottom surface in contact with a loading surface. Accordingly, a user can use the container device in a stable state.

(Configuration 5) The container device described in any one of Configurations 1 to 4, in which the housing has a third member, one end side of the third member being attached to the first member and another end side of the third member being attached to the second member. According to this configuration, the first member and the second member are coupled, even with a third member added to the container portion. Accordingly, the container device has a strength that is further improved.

(Configuration 6) The container device described in Configuration 5, in which a handle is provided on the third member, the handle being for a user to hold. According to this configuration, a handle is provided on the third member fixed to both the first member and the second member. Accordingly, in the container device, the strength is maintained at the time when transporting by holding the handle.

(Configuration 7) The container device described in Configuration 5 or 6, in which at least either a display portion or an operation portion is provided on the third member, the display portion being for displaying information to be provided to a user of the container device, the operation portion being for receiving an operation from the user of the container device. According to this configuration, a display portion or an operation portion is provided on the third member. Accordingly, the container device can improve the operability of a user.

(Configuration 8) The container device described in any one of Configurations 5 to 7, in which the housing has two of the third members, and one of the two of the third members is attached to the first member and the second member on an opposite side of the other one of the third members across the container portion. According to this configuration, the first member and the second member are coupled, by the two of the third members. Accordingly, the container device has a strength that is further improved.

(Configuration 9) The container device described in Configuration 8, in which each of the first member, the second member, and the two of the third members form a frame portion, each of the first member, the second member, and the two of the third members being coupled in a frame shape surrounding the container portion. According to this configuration, the housing includes a frame portion. Accordingly, the container device has a strength that is further improved.

(Configuration 10) The container device described in Configuration 9 includes an accessory component, in which at least a part of the accessory component is disposed more on an inner side than an inner circumference of the frame portion. According to this configuration, maintenance/servicing of the accessory component can be performed, by removing the fourth member. Accordingly, in the container device, maintenance/serviceability of an accessory unit is improved.

(Configuration 11) The container device described in Configuration 10, in which the accessory component is attached to a portion of the container portion positioned more on an inner side than an inner circumference of the frame portion, the accessory component being attached directly or via a support member. According to this configuration, the container device can contain the accessory component with good space efficiency, while the container device suppresses an increase of a fixing structure.

(Configuration 12) The container device described in Configuration 10 or 11, in which the contained item is an electrical storage device, and the accessory component is an electrical accessory unit electrically connected to the electrical storage device contained in the container portion. According to this configuration, the container device can contain the electrical accessory unit with good space efficiency, while the container device suppresses an increase of a fixing structure.

(Configuration 13) The container device described in any one of Configurations 5 to 12, in which the housing has a fourth member attached to the first member, the second member, and the third member. According to this configuration, the fourth member is coupled to the first to third members. Accordingly, in the container device, the fixation of the first to third members can be made firmer by the fourth member.

(Configuration 14) The container device described in Configuration 13, in which an outer surface of the fourth member facing outside of the housing has a main surface positioned in a center, the main surface having a flat portion, and an inclined surface coupled to the main surface, the inclined surface being inclined toward an outer edge. According to this configuration, the housing becomes a shape in which a so-called chamfering is applied, the so-called chamfering having corner portions removed. Accordingly, it is possible for the container device to improve designability, and it is possible for the container device to improve operability relating to transportation, storage, installation or the like.

(Configuration 15) The container device described in Configuration 13 or 14, in which a projecting portion is provided on at least either the container portion or the fourth member, the projecting portion extending toward the other of the container portion or the fourth member. According to this configuration, the fourth member is supported by the container portion. Accordingly, in the container device, the strength of the fourth member can be improved.

(Configuration 16) The container device described in any one of Configurations 13 to 15, in which the housing has two of the fourth members, and one of the two of the fourth members is attached to the first member, the second member, and the third member on an opposite side of the other one of the fourth members across the container portion. According to this configuration, the fourth member is disposed across the container portion. Accordingly, the fourth member can make firmer the fixation of the first to third members with the container portion.

(Configuration 17) The container device described in any one of Configurations 13 to 16, in which the housing is provided to enable the fourth member to be loaded in a vertical direction lower side posture. According to this configuration, the housing can be installed with the fourth member as a bottom surface in contact with a loading surface. Accordingly, the container device can be used in a posture corresponding to a usage condition.

(Configuration 18) The container device described in any one of Configurations 13 to 17, in which the first member forms a first surface being one surface of the six surfaces of the housing, the second member forms a second surface being a surface opposite the first surface of the housing, the third member forms a third surface intersecting the first surface and the second surface of the housing, and the fourth member forms a fourth surface intersecting the first surface, the second surface, and the third surface of the housing. According to this configuration, the housing is formed in a polyhedron shape. Accordingly, the container device can be used in a posture corresponding to a usage condition.

(Configuration 19) The container device described in any one of Configurations 1 to 18, in which the contained item is formed in a rotationally asymmetrical shape through a center of the contained item, and the contained item is formed in a rotationally asymmetrical shape with respect to an axial line extending along a direction in which the contained item is inserted and removed to/from the container portion, the container portion has another frame portion surrounding the axial line, the other frame portion allows insertion of the contained item to the container portion in a case where the contained item is inserted in a predetermined posture with respect to the container portion, and the other frame portion inhibits insertion of the contained item to the container portion in a case where the contained item is inserted in a different posture to the predetermined posture with respect to the container portion. According to this configuration, in the container device, the contained item being stored in an unusable posture is suppressed. Accordingly, in the container device, an operation defect of the container device occurring can be suppressed.

(Configuration 20) The container device described in Configuration 19, in which the other frame portion is formed separate from the container portion. According to this configuration, it is possible for the frame portion to be manufactured by more finely adjusting the shape. Accordingly, in the container device, an exchange of the frame portion is easy, in the case where damaged or the like.

(Configuration 21) The container device described in Configuration 20, in which the other frame portion is formed by a material comprising a higher strength and/or rigidity than a material of the container portion. According to this configuration, the frame portion includes at least either a higher strength or rigidity than a strength or rigidity of the container portion. Accordingly, the frame portion can suppress deformation.

(Configuration 22) The container device described in any one of Configurations 1 to 21, in which the container device has a protruding portion on an inner side surface of the container portion, the protruding portion protruding toward the inside of the container portion. According to this configuration, a gap between an inner circumference of the container portion and an outer circumference of the contained item is reduced. Accordingly, in the container device, positional displacement of the contained item with respect to the container portion can be suppressed.

(Configuration 23) The container device described in any one of Configurations 1 to 22, in which the contained item is an electrical storage device, and the container portion has a connection portion electrically connected to the electrical storage device. According to this configuration, the container device can contain a battery. Accordingly, the container device can use electrical power of the battery.

(Configuration 24) The container device described in Configuration 23, in which at least a part of the connection portion is disposed at a position overlapping the second member in a direction view orthogonal to an alignment direction of the first member, the container portion, and the second member. According to this configuration, the container device can dispose the connection portion with good space efficiency.

(Configuration 25) The container device described in Configuration 23 or 24, in which the container device has an electrical operation portion electrically connected to the connection portion. According to this configuration, the container device can supply electrical power to electrical components. Accordingly, the container device can drive electrical components by using electrical power.

(Configuration 26) The container device described in Configuration 25, in which another support member is provided on the container portion, the other support member supporting the electrical operation portion. According to this configuration, electrical components are supported by the container portion. Accordingly, electrical components are more surely fixed to the housing.

(Configuration 27) The container device described in Configuration 25 or 26, in which the housing has a third member, one end side of the third member being attached to the first member and another end side of the third member being attached to the second member, and at least a part of the electrical operation portion is disposed at a position overlapping the third member in a direction view orthogonal to an alignment direction of the first member, the container portion, and the second member. According to this configuration, the container device can dispose the electrical operation portion with good space efficiency.

### REFERENCE SIGNS LIST

1 container device
10 housing
12 upper surface panel (first member)
13 upper surface opening (second opening)
14 lower surface panel (second member)
16 front surface panel (third member)
18 rear surface panel (third member)
19 side surface panel (fourth member)
20 cover body (cover portion)
22 user interface unit (display portion, operation portion)
28 handle
30 container mechanism
32 battery case (container portion)
31 insertion/removal slot (first opening)
50 case frame body (frame portion)
52 protruding portion
54 case side connection terminal (connection portion)
80 inverter unit (operation device)
100 battery (contained item, electrical storage device)

1. A container device, comprising:
a housing having six substantially quadrangular surfaces facing mutually different directions, the housing being formed in a substantially polyhedral shape; and
a container portion provided inside the housing, the container portion containing a contained item to enable the contained item to be inserted and removed, wherein
the housing has a first member and a second member, the first member and the second member each being attached to the container portion, and
the second member is attached to an opposite side of the first member across the container portion.

2. The container device according to claim 1, wherein
a first opening is provided on the container portion, the first opening enabling the contained item to be inserted and removed, and
the first member is attached at a position of the container portion corresponding to the first opening, and a second opening is provided, the second opening overlapping the first opening, and the second opening enabling the contained item to be inserted and removed.

3. The container device according to claim 2, wherein
a cover portion is provided on the first member, the cover portion covering at least a part of the second opening to enable the at least a part of the second opening to be opened/closed.

4. The container device according to claim 1, wherein
the housing is provided to enable the second member to be loaded in a vertical direction lower side posture.

5. The container device according to claim 1, wherein
the housing has a third member, one end side of the third member being attached to the first member and another end side of the third member being attached to the second member.

6. The container device according to claim 5, wherein
a handle is provided on the third member, the handle being for a user to hold.

7. The container device according to claim 5, wherein
at least either a display portion or an operation portion is provided on the third member,
the display portion being for displaying information to be provided to a user of the container device, the operation portion being for receiving an operation from the user of the container device.

8. The container device according to claim 5, wherein
the housing has two of the third members, and
one of the two of the third members is attached to the first member and the second member on an opposite side of the other one of the third members across the container portion.

9. The container device according to claim 8, wherein
each of the first member, the second member, and the two of the third members form a frame portion, each of the first member, the second member, and the two of the third members being coupled in a frame shape surrounding the container portion.

10. The container device according to claim 9, further comprising:
an accessory component, wherein
at least a part of the accessory component is disposed more on an inner side than an inner circumference of the frame portion.

11. The container device according to claim 10, wherein
the accessory component is attached to a portion of the container portion positioned more on an inner side than an inner circumference of the frame portion, the accessory component being attached directly or via a support member.

12. The container device according to claim 10, wherein
the contained item is an electrical storage device, and
the accessory component is an electrical accessory unit electrically connected to the electrical storage device contained in the container portion.

13. The container device according to claim 5, wherein
the housing has a fourth member attached to the first member, the second member, and the third member.

14. The container device according to claim 13, wherein
an outer surface of the fourth member facing outside of the housing has a main surface positioned in a center, the main surface having a flat portion, and an inclined surface coupled to the main surface, the inclined surface being inclined toward an outer edge.

15. The container device according to claim 13, wherein
a projecting portion is provided on at least either the container portion or the fourth member, the projecting portion extending toward the other of the container portion or the fourth member.

16. The container device according to claim 13, wherein
the housing has two of the fourth members, and
one of the two of the fourth members is attached to the first member, the second member, and the third member on an opposite side of the other one of the fourth members across the container portion.

17. The container device according to claim 13, wherein
the housing is provided to enable the fourth member to be loaded in a vertical direction lower side posture.

18. The container device according to claim 13, wherein
the first member forms a first surface being one surface of the six surfaces of the housing,
the second member forms a second surface being a surface opposite the first surface of the housing,
the third member forms a third surface intersecting the first surface and the second surface of the housing, and
the fourth member forms a fourth surface intersecting the first surface, the second surface, and the third surface of the housing.

19. The container device according to claim 1, wherein
the contained item is formed in a rotationally asymmetrical shape through a center of the contained item, and the contained item is formed in a rotationally asymmetrical shape with respect to an axial line extending along a direction in which the contained item is inserted and removed to/from the container portion,
the container portion has another frame portion surrounding the axial line,
the other frame portion allows insertion of the contained item to the container portion in a case where the contained item is inserted in a predetermined posture with respect to the container portion, and
the other frame portion inhibits insertion of the contained item to the container portion in a case where the contained item is inserted in a different posture to the predetermined posture with respect to the container portion.

20. The container device according to claim 19, wherein
the other frame portion is formed separate from the container portion.

21. The container device according to claim 20, wherein
the other frame portion is formed by a material comprising a higher strength and/or rigidity than a material of the container portion.

22. The container device according to claim 1, wherein
the container device has a protruding portion on an inner side surface of the container portion, the protruding portion protruding toward the inside of the container portion.

23. The container device according to claim 1, wherein
the contained item is an electrical storage device, and
the container portion has a connection portion electrically connected to the electrical storage device.

24. The container device according to claim 23, wherein
at least a part of the connection portion is disposed at a position overlapping the second member in a direction view orthogonal to an alignment direction of the first member, the container portion, and the second member.

25. The container device according to claim 23, wherein
the container device has an electrical operation portion electrically connected to the connection portion.

26. The container device according to claim 25, wherein
another support member is provided on the container portion, the other support member supporting the electrical operation portion.

27. The container device according to claim 25, wherein
the housing has a third member, one end side of the third member being attached to the first member and another end side of the third member being attached to the second member, and
at least a part of the electrical operation portion is disposed at a position overlapping the third member in a direction view orthogonal to an alignment direction of the first member, the container portion, and the second member.
